(19) United States
(12) Patent Application Publication
(10) Pub. No.: US 2026/0150286 A1
(43) Pub. Date: May 28, 2026

(54) MICROELECTRONIC DEVICES, AND RELATED METHODS AND ELECTRONIC SYSTEMS

(71) Applicant: Micron Technology, Inc., Boise, ID (US)

(72) Inventors: Anna Maria Conti, Milano (IT); Matthew J. King, Boise, ID (US); Terry H. Kim, Boise, ID (US)

(21) Appl. No.: 19/389,925

(22) Filed: Nov. 14, 2025

Related U.S. Application Data
(60) Provisional application No. 63/723,875, filed on Nov. 22, 2024.

(51) Int. Cl. H10B 43/10; H10B 41/10; H10B 41/27; H10B 43/27

(52) U.S. Cl. CPC H10B 43/10; H10B 41/10; H10B 41/27; H10B 43/27

(57) ABSTRACT

A microelectronic device includes a stack structure and block isolation structures vertically extending completely through the stack structure. The stack structure comprises levels of conductive material vertically alternating with levels of insulative material. The stack structure includes an array region and a contact region horizontally offset from the array region in a first direction. The stack structure is divided into blocks, and the block isolation structures horizontally alternating with the blocks in a second direction orthogonal to the first direction. At least one of the block isolation structures includes a first portion and a second portion horizontally overlapping the array region and contact region, respectively of each of two of the blocks in the first direction. The first portion extends horizontally in a substantially linear path in the first direction. The second portion extends horizontally in a non-linear path in the first direction and the second direction.

### CROSS-REFERENCE TO RELATED APPLICATIONS

This application claims the benefit under 35 U.S.C. § 119(e) of U.S. Provisional Patent Application Ser. No. 63/723,875, filed Nov. 22, 2024, the disclosure of which is hereby incorporated herein in its entirety by this reference.

### TECHNICAL FIELD

The disclosure, in various embodiments, relates generally to microelectronic device design and fabrication. More particularly, the disclosure relates to microelectronic devices, memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. A continuing goal of the electronics industry has been to increase the memory density (e.g., the number of memory cells per memory die) of memory devices, such as non-volatile memory devices (e.g., NAND flash memory devices). One way of increasing memory density in non-volatile memory devices is to utilize vertical memory array (also referred to as a “three-dimensional memory array”) architectures. A conventional vertical memory array includes vertical memory strings extending through one or more stack structures having vertically alternating sequence of conductive structures and insulative structures. Each vertical memory string may include at least one select device coupled in series to a serial combination of vertically-stacked memory cells. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

In the three-dimension memory devices (e.g., 3D NAND memory device), the conductive structures of the tiers of the stack structures may function as control gates for access lines (e.g., word lines) of the memory cells. The access lines are electrically connected with other conductive structures of the memory device so that the memory cells of the vertical memory strings can be selected for writing, reading, and erasing operation. One method of forming such an electrical connection includes forming so-called “staircase” structures at edges (e.g., horizontal ends) of the conductive structures of the stack structures of the memory device. The staircase structure includes individual “steps” defining contact regions upon which conductive contacts can be formed for electrical connection to the conductive structures such as the access line of the memory cells. As vertical memory array technology has advanced, additional memory density has been provided by increasing levels of the conductive structures in the stack structure of the vertical memory array, and thereby demanding additional staircase structures and/or additional steps in individual staircase structures associated therewith. As a result, the horizontal dimension of the staircase structure continues to increase to allow for sufficient electrical connection between the access lines of the memory cells and other conductive structures within the device. The continuing increase in the horizontal dimension of staircase structure can interfere with efforts to increase the memory density and reduce the overall horizontal footprints of the memory devices.

### BRIEF DESCRIPTION OF THE DRAWINGS

FIG. 1 shows a schematic, top-down view of a portion of a microelectronic device;

FIG. 2 shows a schematic, top-down view of a portion of a microelectronic device, according to some embodiments of the disclosure;

FIG. 3A through FIG. 13 are simplified, vertical cross-sectional views of portions of a microelectronic device structure at various processing stages for a method of forming a microelectronic device, according to some embodiments of the disclosure;

FIG. 14 shows a schematic, top-down view of a portion of a microelectronic device after the processing stage shown in FIG. 13, according to some embodiments of the disclosure;

FIG. 15 through FIG. 18 are simplified, vertical cross-sectional views of further processing stages in a method of forming a microelectronic device, according to some embodiments of the disclosure;

FIG. 19 shows a schematic top-down view of a portion of a microelectronic device structure after the process stage described with reference to FIG. 18;

FIG. 20A through FIG. 24 are simplified, vertical cross-sectional views of further processing stages in a method of forming a microelectronic device, according to some embodiments of the disclosure;

FIG. 25 shows schematic, top-down view of a portion of a microelectronic device, according to some embodiments of the disclosure;

FIG. 26 shows a schematic, top-down view of a portion of a microelectronic device, according to some embodiments of the disclosure;

FIG. 27 shows schematic, top-down view of a portion of a microelectronic device, according to some embodiments of the disclosure; and

FIG. 28 is a schematic block diagram illustrating an electronic system, in accordance with embodiments of the disclosure.

### DETAILED DESCRIPTION

The following description provides specific details, such as material types, material thicknesses, and processing conditions in order to provide a thorough description of embodiments of the disclosure. However, a person of ordinary skill in the art will understand that embodiments of the present disclosure may be practiced without employing these specific details. Indeed, the embodiments of the present disclosure may be practiced in conjunction with conventional fabrication techniques employed in the industry. In addition, the description provided herein does not form a complete process flow for forming a semiconductor device structure, and the semiconductor device structures described below do not form a complete semiconductor device. Only those process acts and structures necessary to understand the embodiments of the present disclosure are described in detail below. Additional acts to form the complete semiconductor device may be performed by conventional fabrication techniques.

Unless otherwise indicated, the materials described herein may be formed by conventional techniques including, but not limited to, spin coating, blanket coating, chemical vapor deposition (CVD), atomic layer deposition (ALD), plasma enhanced ALD, physical vapor deposition (PVD) (including sputtering, evaporation, ionized PVD, and/or plasma-enhanced CVD), or epitaxial growth. Alternatively, the materials may be grown in situ. Depending on the specific material to be formed, the technique for depositing or growing the material may be selected by a person of ordinary skill in the art. The removal of materials may be accomplished by any suitable technique including, but not limited to, etching (e.g., dry etching, wet etching, vapor etching), ion milling, abrasive planarization (e.g., chemical-mechanical planarization), or other known methods unless the context indicates otherwise.

Drawings presented herein are for illustrative purposes only, and are not meant to be actual views of any particular material, component, structure, electronic device, or electronic system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. Furthermore, the drawings accompanying the application are for illustrative purposes only, and are thus not necessarily drawn to scale. Elements common between figures may retain the same numerical designation. While the materials described and illustrated herein may be formed as layers, the materials are not limited thereto and may be formed in other three-dimensional configurations.

As used herein, the singular forms “a,” “an,” and “the” are intended to include the plural forms as well, unless the context clearly indicates otherwise.

As used herein, “and/or” includes any and all combinations of one or more of the associated listed items.

As used herein, relational terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the drawings. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the drawings, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., materials, structures, regions, circuitry, devices) described as “neighboring” one another means and includes features of the disclosed identity (or identities) that are located most proximate (e.g., closest to) one another. Additional features (e.g., additional regions, additional structures, additional regions, additional circuitry, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, reference to an element as being “on” or “over” another element means and includes the element being directly on top of, directly adjacent to (e.g., directly laterally adjacent to, directly vertically adjacent to), directly underneath, or in direct contact with the other element. It also includes the element being indirectly on top of, indirectly adjacent to (e.g., indirectly laterally adjacent to, indirectly vertically adjacent to), indirectly underneath, or near the other element, with other elements present therebetween. In contrast, when an element is referred to as being “directly on” or “directly adjacent to” another element, there are no intervening elements present.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, the term “about” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 108.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “memory device” means and includes microelectronic devices exhibiting memory functionality, but not necessarily limited to memory functionality. Stated another way, and by way of example only, the term “memory device” means and includes not only memory (e.g., volatile memory, such as dynamic random access memory (DRAM); non-volatile memory, such as NAND memory), but also includes an application specific integrated circuit (ASIC) (e.g., a system on a chip (SoC)), an electronic device combining logic and memory, or a graphics processing unit (GPU) incorporating memory.

As used herein, “electronic device” includes, without limitation, a memory device, as well as a semiconductor device which may or may not incorporate memory, such as a logic device, a processor device, or a radiofrequency (RF) device. Further, an electronic device may incorporate memory in addition to other functions such as, for example, a so-called “system on a chip” (SoC) including a processor and memory, or an electronic device including logic and memory. The electronic device may, for example, be a 3D electronic device, such as a 3D NAND Flash memory device.

As used herein, “substrate” means and includes a base material or construction upon which additional materials are formed. The substrate may be, for example, a semiconductor substrate, a base semiconductor material on a supporting structure, a metal electrode or a semiconductor substrate having one or more materials, structures or regions formed thereon. The substrate may be a conventional silicon substrate, or other bulk substrate comprising a layer of semiconductive material. As used herein, the term “bulk substrate” means and includes not only silicon wafers, but also silicon-on-insulator (SOI) substrates, such as silicon-on-sapphire (SOS) substrates and silicon-on-glass (SOG) substrates, epitaxial layers of silicon on a base semiconductor foundation, or other semiconductor or optoelectronic materials, such as silicon-germanium (Si₁₋ₓGeₓ, where x is, for example, a mole fraction between 0.2 and 0.8), germanium (Ge), gallium arsenide (GaAs), gallium nitride (GaN), or indium phosphide (InP), among others. The substrate may be doped or undoped. By way of non-limiting example, a substrate may comprise at least one of silicon, silicon dioxide, silicon with native oxide, silicon nitride, a carbon-containing silicon nitride, glass, semiconductor, metal oxide, metal, titanium nitride, carbon-containing titanium nitride, tantalum, tantalum nitride, carbon-containing tantalum nitride, niobium, niobium nitride, carbon-containing niobium nitride, molybdenum, molybdenum nitride, carbon-containing molybdenum nitride, tungsten, tungsten nitride, carbon-containing tungsten nitride, copper, cobalt, nickel, iron, aluminum, and a noble metal.

As used herein, “conductive material” means and includes an electrically conductive material, such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). As used herein, an “insulative structure” means and includes a structure formed of and including one or more insulative materials. As used herein, an “dielectric structure” means and includes a structure formed of and including one or more dielectric materials.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, each of a “microelectronic device structure” and a “semiconductive structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “selectively removable” means and includes a material that exhibits a greater removal rate responsive to exposure to a given removing (e.g., etching) chemistry and/or process conditions relative to another material exposed to the same removal chemistry and/or process conditions. For example, the material may exhibit a removal rate that is at least about five times greater than the removal rate of another material, such as a removal rate of about ten times greater, about twenty times greater, or about forty times greater than the removal rate of the another material. Removal chemistries and conditions (e.g., etch chemistries and etch conditions) for selectively removing a desired material may be selected by a person of ordinary skill in the art.

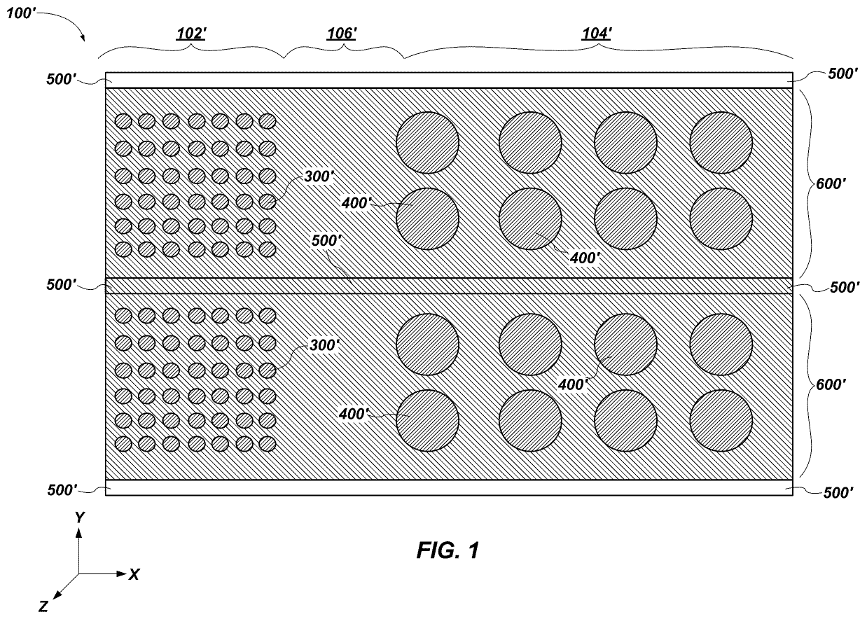

FIG. 1 shows a schematic, top-down view of a portion of a microelectronic device structure 100′. The microelectronic device structure 100′ includes an array region 102′, a connecting region 106′ horizontally adjacent the array region 102′ in a first horizontal direction (e.g., an X-direction), and a contact region 104′ horizontally adjacent the connecting region 106′ in the first horizontal direction. In the array region 102′, cell pillar structures 300′ may be arranged in rows horizontally extending in parallel in the first horizontal direction (e.g., the X-direction) and columns horizontally extending in parallel in a second horizontal direction (e.g., a Y-direction) orthogonal to the first horizontal direction. In the contact region 104′, conductive contact structures 400′ may be arranged in rows horizontally extending in parallel in the first horizontal direction, and columns horizontally extending in parallel in the second horizontal direction. The microelectronic device structure 100′ is divided into blocks 600′ horizontally separated from one another by block isolation structures 500′. The block isolation structures 500′ horizontally extend in parallel in the first horizontal direction through the array region 102′, the contact region 104′, and the connecting region 106′ of the microelectronic device structure 100′ in substantially linear paths.

To increase the level of integration or density of features (e.g., memory density) within a microelectronic device structure, it is desirable to include a higher number of conductive contacts 400′ within individual blocks 600′ of the microelectronic device structure 100′ to facilitate sufficient electrical communication with an increased quantity of memory cells (e.g., non-volatile memory cells) within the blocks of the microelectronic device structure.

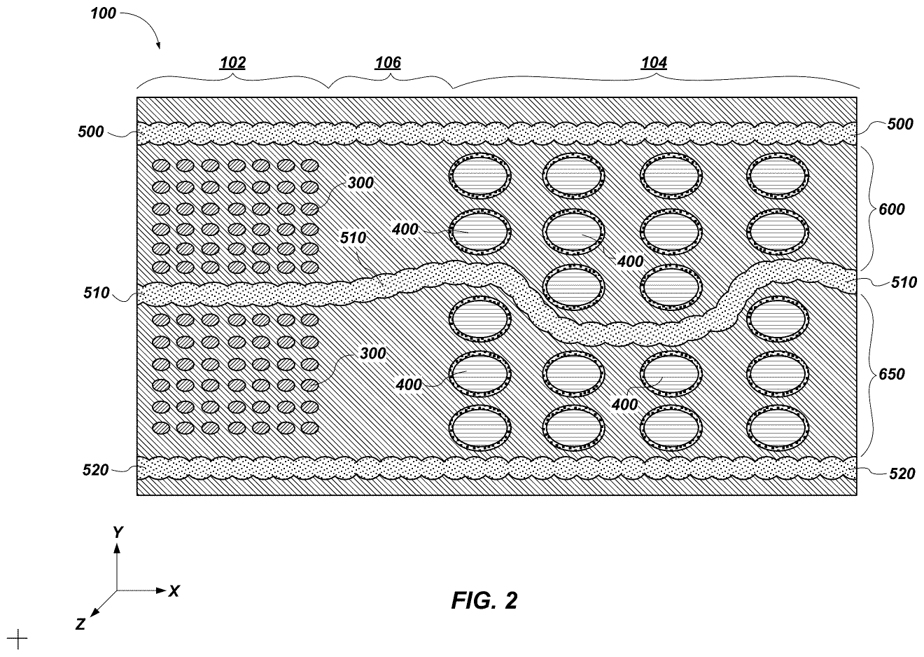

FIG. 2 shows a schematic, top-down view of a portion of a microelectronic device structure 100, according to some embodiments of the disclosure. The microelectronic device structure 100 may be formed to include an array region 102, a connecting region 106 horizontally adjacent the array region 102 in a first horizontal direction (e.g., in X-direction), and a contact region 104 horizontally adjacent the connecting region 106 in a first horizontal direction. In the array region 102, cell pillar structures 300 may be arranged in rows and columns. The cell pillar structures 300 may individually define a string of memory cells extending vertically (e.g., in Z-direction) through a stack structure including vertically alternating sequence of insulative material and conductive material arranged in tiers, as described in further detail below. In the contact region 104, conductive contact structures 400 may be arranged in rows and columns. The conductive contact structures 400 individually extend vertically into portions of the stack structure, and may be configured to facilitate electrical communication with the cell pillar structures 300 in the array region 102, as also described in further detail below.

The microelectronic device structure 100 is divided into blocks 600, 650 horizontally separated from one another by block isolation structures 500, 510, 520. For example, the block isolation structure 510 may be between neighboring blocks 600 and 650 in a second horizontal direction (e.g., in Y-direction). The block isolation structures 500, 510, 520 are spaced apart from each other horizontally in a second horizontal direction (e.g., in Y-direction), with the block isolation structure 510 positioned between the block isolation structure 500 and the block isolation structure 520. The block isolation structures 500, 510, 520 respectively extend vertically completely through the stack structure of the microelectronic device structure 100, and may respectively extend laterally in at least the first horizontal direction (e.g., in X-direction) through portions of the array region 102, the contact region 104, and the connecting region 106 of the microelectronic device structure 100. The block isolation structures 500 and 520 respectively extend laterally through the array region 102, the contact region 104, and the connecting region 106 of the microelectronic device structure 100 in a substantially linear path. The block isolation structure 510 extends laterally through array region 102, the contact region 104, and the connecting region 106 in a partially non-linear path. For example, a portion with block isolation structure 510 within the array region 102 may laterally extend in a substantially linear path, and an additional portion of the block isolation structure 510 within contact region 104 may laterally extend in a non-linear path (e.g., winding path, a curved path, a wavy path). The non-linear path of the block isolation structure 510 within the contact region 104 may permit the microelectronic device structure 100 to have a relatively greater number of conductive contact structures 400 within blocks 600 and 650 as compared to a conventional configuration not having such non-linear pathing of a block isolation structure. Therefore, a microelectronic device including the microelectronic device structure 100 may have a relatively greater density of features (e.g., conductive contact structures 400) as compared to conventional microelectronic devices.

FIG. 2 depicts each of the cell pillar structures 300 and the conductive contact structures 400 as having a substantially circular horizontal cross-sectional shape. However, the disclosure is not so limited, and additional configurations of the cell pillar structures 300 and/or the conductive contact structures 400 may be contemplated. For example, one or more of the cell pillar structures 300 and/or one or more of the conductive contact structures 400 may individually exhibit a generally ovular horizontal cross-sectional shape, a generally elliptical horizontal cross-sectional shape, a generally rectangular horizontal cross-sectional shape, or a generally square horizontal cross-sectional shape.

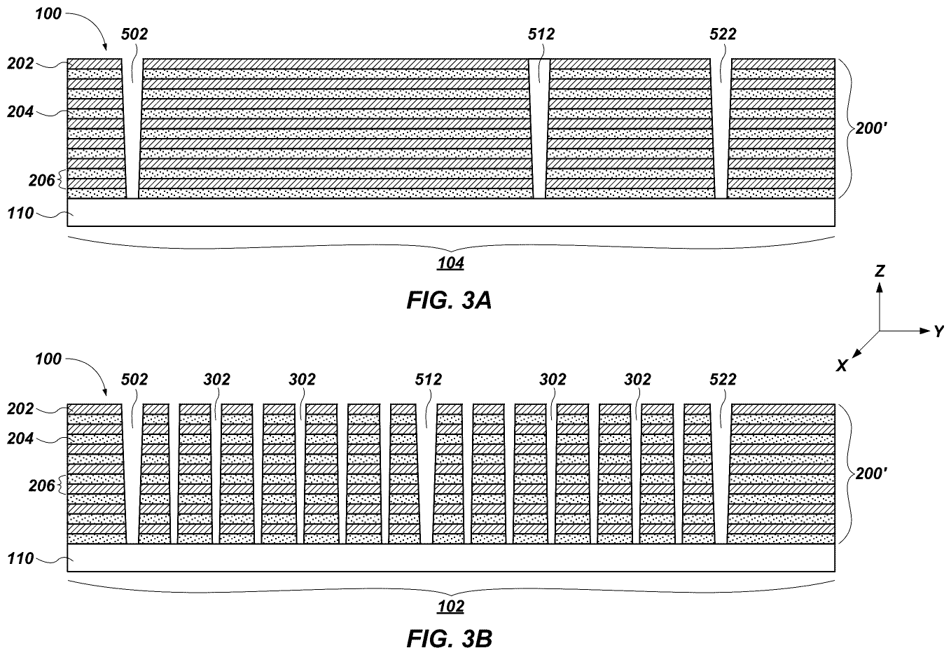

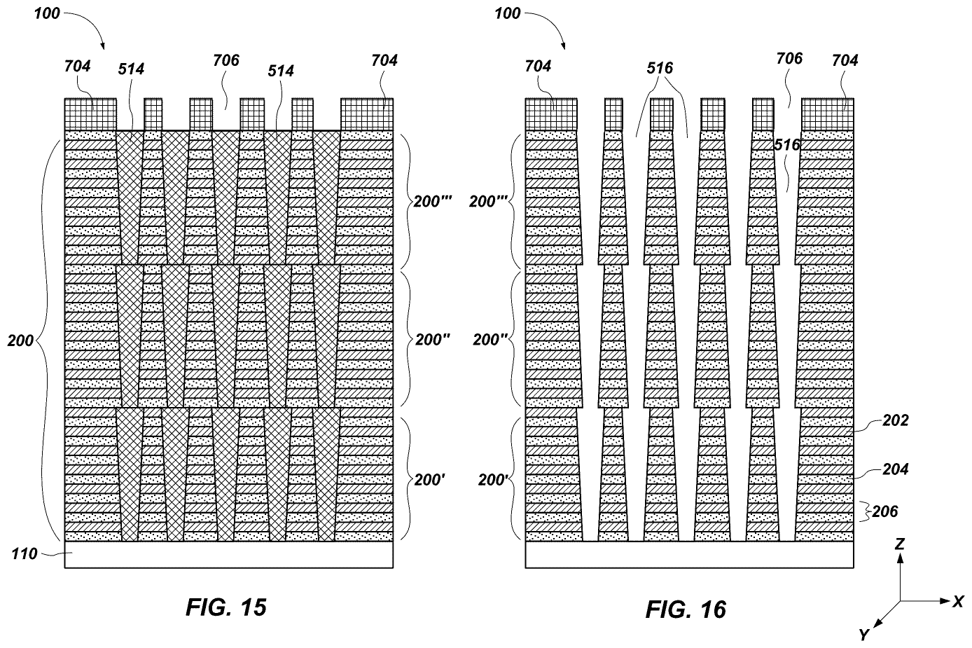

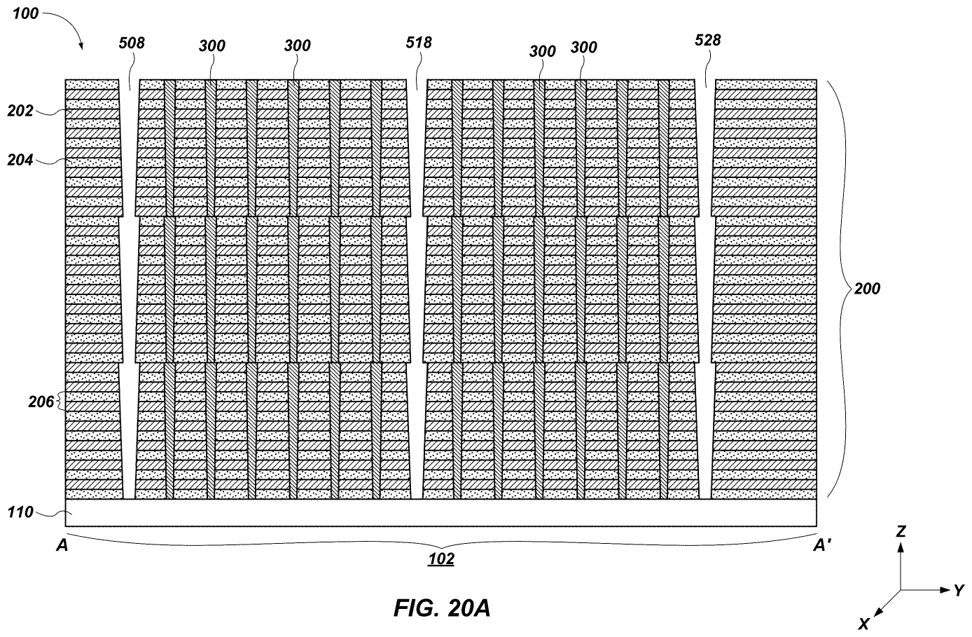

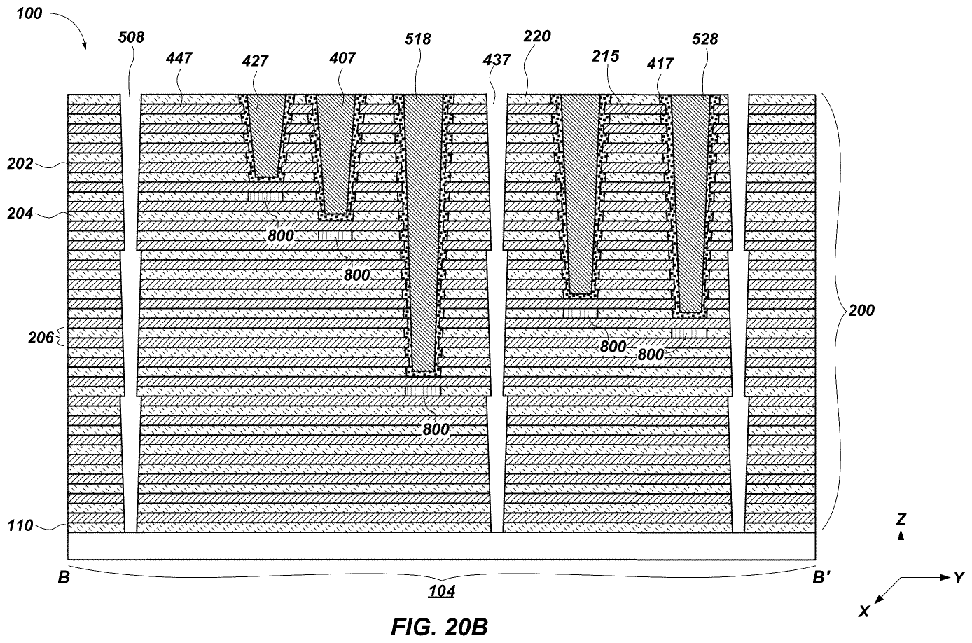

FIG. 3A through FIG. 13, FIG. 15 through FIG. 18, and FIG. 20A through FIG. 24 are simplified, vertical cross-sectional views of portions of a microelectronic device structure 100 (e.g., a memory device structure) at various processing stages for a method of forming a microelectronic device (e.g., a memory device, such as a 3D NAND Flash memory device), according to some embodiments of the disclosure. As described in further detail below, the method described with reference to FIG. 3A through FIG. 13, FIG. 15 through FIG. 18, and FIG. 20A through FIG. 24 may effectuate the formation of a microelectronic device having increased level of integration or density of features relative to conventional microelectronic devices.

Referring collectively to FIGS. 3A and 3B, the microelectronic device structure 100 is formed to include a preliminary deck structure 200′ over a substrate 110. The substrate 110 may, for example, include at least one source structure (e.g., source plate) to be in electrical communication with the cell pillar structures 300 (FIG. 2) that will be formed in later processing stages. The preliminary deck structure 200′ is formed to include a vertically alternating sequence of insulative material 202 and sacrificial material 204 (e.g., additional insulative material) arranged in tiers 206. Each of the tiers 206 may individually include a level of the insulative material 202 vertically neighboring (e.g., adjacent) a level of the sacrificial material 204. FIG. 3A shows the contact region 104 of the microelectronic device structure 100, and FIG. 3B shows the array region 102 of the microelectronic device structure 100.

Each level (e.g., vertical elevation) of the insulative material 202 and the sacrificial material 204 may respectively have a desired vertical thickness. Each level of the insulative material 202 may have substantially the same vertical thickness as one another, or at least one level of the insulative material 202 may have a different vertical thickness than at least one other level of the insulative material 202. Furthermore, each level of the sacrificial material 204 may have substantially the same vertical thickness as one another, or at least one level of the sacrificial material 204 may have a different thickness than at least one other level of the sacrificial material 204. In some embodiments, the insulative material 202 and the sacrificial material 204 respectively have a vertical thickness within a range of from about 10 nanometers (nm) to about 400 nm. In some embodiments, the insulative material 202 and the sacrificial material 204 respectively have a vertical thickness within a range of from about 10 nm to about 50 nm, such as from about 20 nm to about 50 nm.

In FIGS. 3A and 3B, the preliminary deck structure 200′ is shown as having seven (7) levels of the insulative material 202 and seven (7) levels of the sacrificial material 204. However, the disclosure is not limited; and fewer or more levels of the insulative material 202 and/or the sacrificial material 204 may be included in the preliminary deck structure 200′. A quantity of vertically alternating levels of the insulative material 202 and/or the sacrificial material 204 may, for example, be within a range from about two (2) to about one-thousand and twenty-four (1024). In addition, the levels of the insulative material 202 and/or the sacrificial material 204 may be arranged in tiers 206 within the preliminary deck structure 200′, wherein an individual tier 206 includes one of the levels of the insulative material 202 vertically neighboring one of the levels of the sacrificial material 204.

The insulative material 202 of the preliminary deck structure 200′ may be formed of and include at least one insulative material having different etch selectivity than the sacrificial material 204 of the preliminary deck structure 200′. In some embodiments, the insulative material 204 is formed of and includes SiOₓ (e.g., SiO₂). The sacrificial material 204 of the preliminary deck structure 200′ may be formed of and include at least one material that can be removed selectively relative to the insulative material 202. As a non-limiting example, the sacrificial material 204 may be removed at etch rate that is at least two times (2×) faster than an etch rate of the insulative material 202 during mutual exposure to an etchant (e.g., a wet etchant). The sacrificial material 204 may, for example, be formed of and include one or more of insulative material, semiconductor material, and conductive material. In some embodiments, the sacrificial material 204 is formed of and includes SiN_{y} (e.g., Si₃N₄).

Still referring to FIGS. 3A and 3B, inter-block openings 502, 512, 522 are formed in the contact region 104 (FIG. 3A) and the array region 102 (FIG. 3B) of the microelectronic device structure 100. The inter-block openings 502, 512, 522 respectively extend vertically (e.g., in Z-direction) through the preliminary deck structure 200′. For the array region 102, as shown in FIG. 3B, cell openings 302 may be formed between horizontally neighboring inter-block openings. Each of the cell openings 302 extends vertically through the preliminary deck structure 200′ and is spaced from other cell openings 302 laterally (e.g., in Y-direction).

In some embodiments, the inter-block openings 502, 512, 522 are formed substantially simultaneously with the cell openings 302. For example, the inter-block openings 502, 512, 522 and the cell openings 302 may be formed using a single material removal process (e.g., anisotropic etching process employing a shared masking structure). In additional embodiments, the inter-block openings 502, 512, 522 are not formed substantially simultaneously with the cell openings 302. For example, all of the inter-block openings 502, 512, 522 may be formed sequentially with (e.g., before or after) the formation of all of the cell openings 302, or some of the inter-block openings 502, 512, 522 may be formed sequentially with (e.g., before or after) the formation of at least some of the cell openings 302. At least some of the inter-block openings 502, 512, 522 may be formed using a material removal process (e.g., an anisotropic etching process employing a masking structure), and at least some of the cell openings 302 may be formed using another, different material removal process (e.g., another anisotropic etching process employing another, different masking structure, such as a modified form of the masking structure). The inter-block openings 502, 512, 522 may be formed to have substantially the same geometric configuration as one another and the cell openings 302, or at least some of the inter-block openings 502, 512, 522 may be formed to have a different geometric configuration than at least some other of the inter-block openings 502, 512, 522 and/or at least some of the cell openings 302.

In FIGS. 3A and 3B, the microelectronic device structure 100 is shown as having certain numbers of the inter-block openings 502, 512, 522 and the cell openings 302. However, the disclosure is not limited, and fewer or more numbers of the inter-block openings 502, 512, 522, and/or the cell openings 302 may be formed in the preliminary deck structure 200′ of the microelectronic device structure 100.

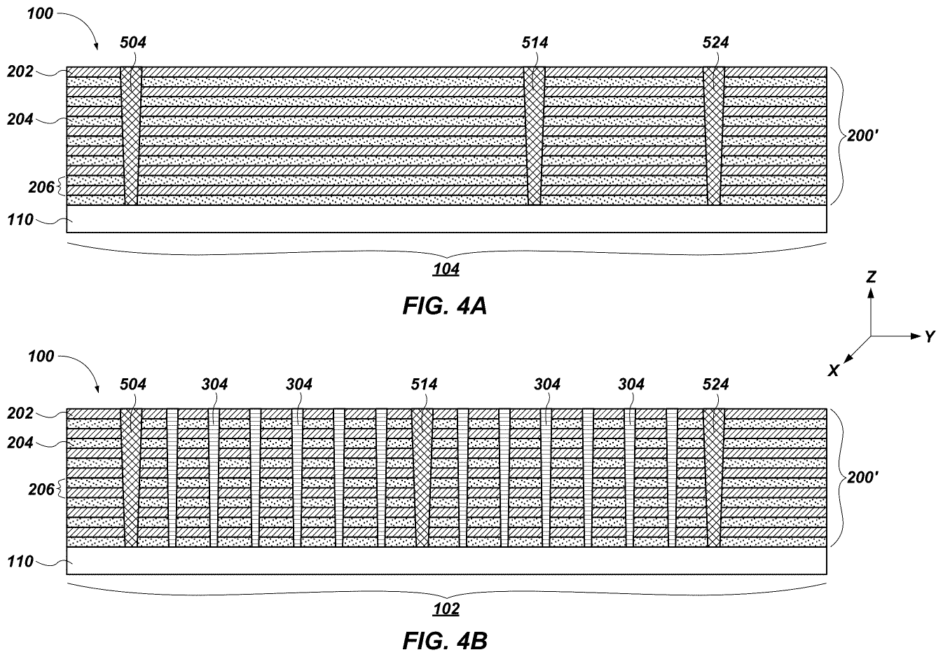

Referring collectively to FIGS. 4A and 4B, the inter-block openings 502, 512, 522 (FIGS. 3A and 3B) in the contact region 104 (FIG. 4A) and the array region 102 (FIG. 4B) of the microelectronic device structure 100 may be filled (e.g., substantially filled) with a first sacrificial material to form sacrificially filled inter-block openings 504, 514, 524, respectively. For instance, the first sacrificial material may be formed within the inter-block openings 502, 512, 522 through a non-conformal deposition process, such as a spin-on coating process, followed by a planarization process (e.g., a CMP process). In some embodiments, the first sacrificial material is formed of and includes spin-on carbon. The cell openings 302 (FIG. 3B) in the array region 102 of the microelectronic device structure 100 may be filled (e.g., substantially filled) with a second sacrificial material to form sacrificially filled cell openings 304. In some embodiments, a material composition of the first sacrificial material is the same as a material composition of the second sacrificial material. In additional embodiments, the material composition of the first sacrificial material is different than a material composition of the second sacrificial material. At least one of the first sacrificial material and the second sacrificial material may be formed of and include, for example, an oxide material (e.g., silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide); a nitride material (e.g., silicon nitride), an oxynitride material (e.g., silicon oxynitride), a dielectric carbon nitride material (e.g., silicon carbon nitride), a dielectric carboxynitride material (e.g., silicon carboxynitride), or combinations thereof. In some embodiments, the first sacrificial material and/or the second sacrificial material is formed of and includes spin-on carbon. Although other materials may be contemplated, so long as the first sacrificial material and the second sacrificial material may be selectively removed relative to surrounding materials, e.g., in the subsequent processing stages as discussed below.

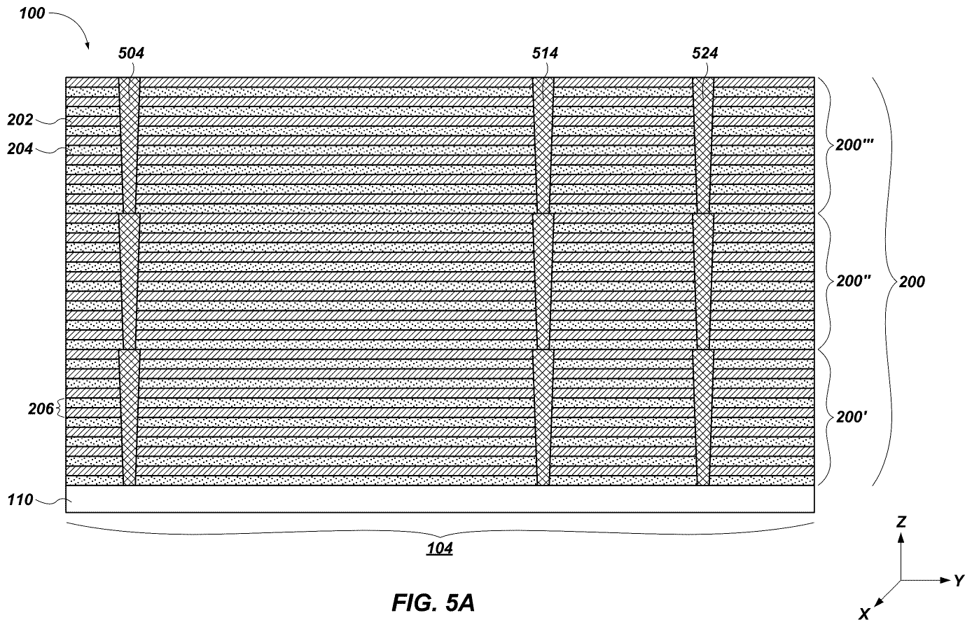

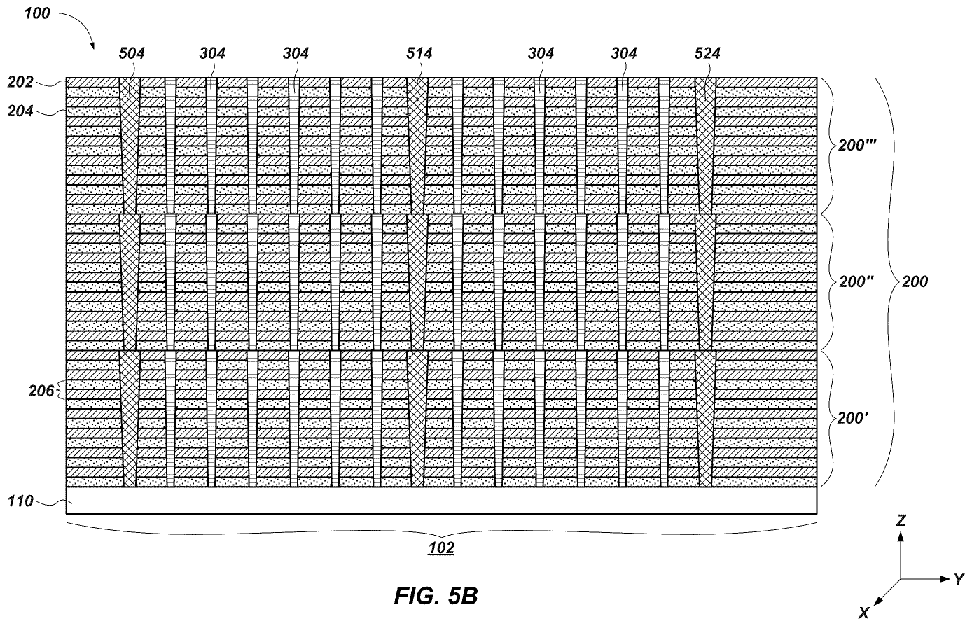

Collectively referring next to FIGS. 5A and 5B, an additional preliminary deck structure 200″ is formed vertically over the preliminary deck structure 200′, and may include an additional vertically alternating sequence of the insulative material 202 and the sacrificial material 204. The additional preliminary deck structure 200″ may also be formed to include the sacrificially filled inter-block openings 504, 514, 524 in the contact region 104 (FIG. 5A) and the array region 102 (FIG. 5B). The sacrificially filled inter-block openings 504, 514, 524 of the additional preliminary deck structure 200″ extend vertically through the additional preliminary deck structure 200″, and may horizontally overlap (e.g., substantially horizontally align with) respective sacrificially filled inter-block openings 504, 514, 524 of the preliminary deck structure 200′. The additional preliminary deck structure 200″ may also be formed to include sacrificially filled cell openings 304 in the array region 102 (FIG. 5B). Each of the sacrificially filled cell openings 304 of the additional preliminary deck structure 200″ may extend vertically through the additional preliminary deck structure 200″ and may horizontally overlap (e.g., substantially horizontally align with) a respective sacrificially filled cell opening 304 of the preliminary deck structure 200′. The sacrificially filled inter-block openings 504, 514, 524 and the sacrificially filled cell openings 304 of the additional preliminary deck structure 200″ may be formed using processing methodology substantially similar to that previously described with reference to FIGS. 3A through 4B for the formation of the sacrificially filled inter-block openings 504, 514, 524 and the sacrificially filled cell openings 304 of the preliminary deck structure 200′.

Thereafter, a further preliminary deck structure 200″′ may be formed vertically over the additional preliminary deck structure 200″, and may include a further vertically alternating sequence of the insulative material 202 and the sacrificial material 204. The further preliminary deck structure 200″′ is also formed to include the sacrificially filled inter-block openings 504, 514, 524 in the contact region 104 (FIG. 5A) and the array region 102 (FIG. 5B). The sacrificially filled inter-block openings 504, 514, 524 of the further preliminary deck structure 200″′ extend vertically through the further preliminary deck structure 200″′, and may horizontally overlap (e.g., substantially horizontally align with) the respective sacrificially filled inter-block openings 504, 514, 524 of the additional preliminary deck structure 200″. The further preliminary deck structure 200″′ may also be formed to include sacrificially filled cell openings 304 in the array region 102 (FIG. 5B). Each of the sacrificially filled cell openings 304 of the further preliminary deck structure 200″′ may extend vertically through the further preliminary deck structure 200″′, and may horizontally overlap (e.g., substantially horizontally align with) a respective underlying sacrificially filled cell opening 304 of the additional preliminary deck structure 200″. The sacrificially filled inter-block openings 504, 514, 524 and the sacrificially filled cell openings 304 of the further preliminary deck structure 200″′ may be formed using processing methodology substantially similar to that previously described with reference to FIGS. 3A through 4B for the formation of the sacrificially filled inter-block openings 504, 514, 524 and the sacrificially filled cell openings 304 of the preliminary deck structure 200′.

A vertical stack of the preliminary deck structure 200′, the additional preliminary deck structure 200″, and the further preliminary deck structure 200″′ is referred herein as a preliminary stack structure 200. In other words, the preliminary stack structure 200 is formed to include the vertically alternating sequence of insulative material 202 and sacrificial material 204; the sacrificially filled inter-block openings 504, 514, 524 in the contact region 104 (FIG. 5A) and the array region 102 (FIG. 5B) extending vertically through the preliminary stack structure 200; and sacrificially filled cell openings 304 in the array region 102 (FIG. 5B) extending vertically through the preliminary stack structure 200.

In FIGS. 5A and 5B, the preliminary stack structure 200 is shown as including three preliminary deck structures 200′, 200″, 200″′. However, the disclosure is not limited; and the preliminary stack structure 200 may be formed to include a different number of preliminary deck structures (e.g., one preliminary deck structure, two preliminary deck structures, more than three preliminary deck structures). Furthermore, each of the preliminary deck structures 200′, 200″, 200″′ in FIGS. 5A and 5B is shown as having the same numbers of tiers 206 as one another sacrificial material. However, the disclosure is not limited; and one or more of the preliminary deck structures 200′, 200″, 200″′ of the preliminary stack structure 200 may have a different number of tiers 206 relative to one or more other of the preliminary deck structures 200′, 200″, 200″′ of the preliminary stack structure 200.

In FIGS. 5A and 5B, the preliminary stack structure 200 is shown as having the additional preliminary deck structures 200″ directly vertically on the preliminary deck structures 200′, and the further preliminary deck structure 200″′ directly vertically on the additional preliminary deck structure 200″. However, the disclosure is not limited; and the preliminary stack structure 200 may be formed to include, in some embodiments, one or more inter-deck regions between the vertically neighboring preliminary deck structures 200′, 200″, 200″′.

Moreover, in some embodiments, the preliminary stack structure 200 is formed to include a dielectric material over an uppermost one of the tiers 206 of the preliminary stack structure 200. In some embodiments, the dielectric material has a same material composition as the insulative material 202 of the tiers 206. In some embodiments, the dielectric material is formed of and includes silicon dioxide.

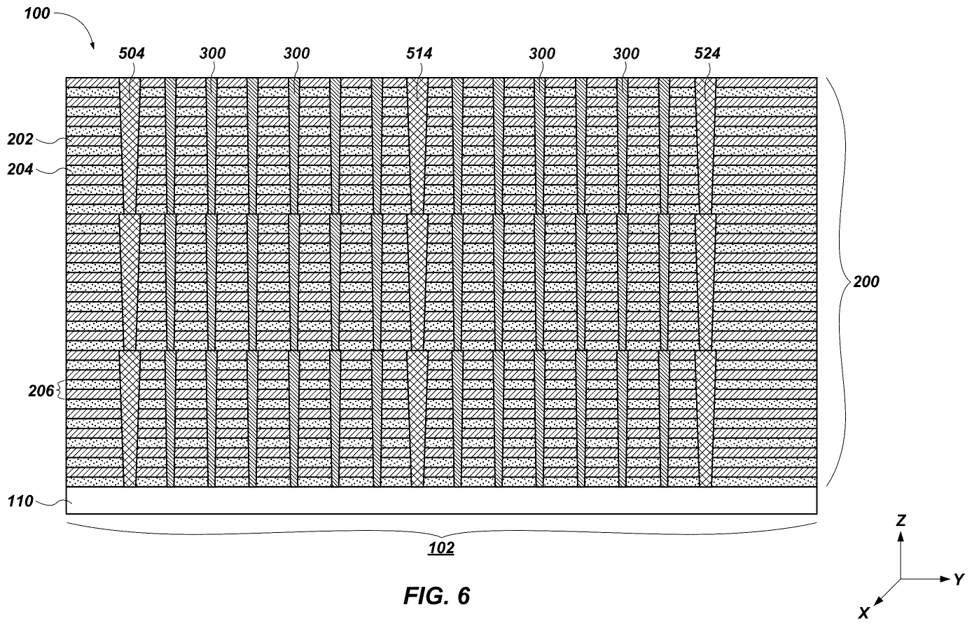

Referring to FIG. 6, the second sacrificial material of the sacrificially filled cell openings 304 (FIG. 5B) is selectively removed while substantially maintaining the first sacrificial material of the sacrificially filled inter-block openings 504, 514, 524. Then, the resulting cell openings may be filled with cell materials to form the cell pillar structures 300 extending vertically through the preliminary stack structure 200. The cell pillar structures 300 may respectively be formed to include a stack of materials that collectively facilitate the formation of a vertically extending string of memory cells following subsequent processing of the microelectronic device structure 100, as described in further detail below. For example, the cell pillar structures 300 may respectively be formed to include a charge-blocking material, such as a first dielectric oxide material (e.g., SiOₓ, such as SiO₂; AlOₓ, such as Al₂O₃); a charge-trapping material, such as a dielectric nitride material (e.g., SiN_{y}, such as Si₃N₄); a tunnel dielectric material, such as a second oxide dielectric material (e.g., SiOₓ, such as SiO₂); a channel material, such as a semiconductor material (e.g., silicon, such as polycrystalline Si); and a fill material, such a dielectric fill material (e.g., dielectric oxide, dielectric nitride, air). The charge-blocking material may be formed on or over, and may substantially cover surfaces of the preliminary stack structure 200 defining boundaries (e.g., horizontal boundaries, lower vertical boundaries) of the cell openings, such as surfaces of the levels of insulative material 202 and the sacrificial material 204 of the tiers 206 of the preliminary stack structure 200. The charge-trapping material may be formed on or over inner surfaces of the charge-blocking material. The tunnel dielectric material may be formed on or over inner surfaces of the charge-trapping material. The channel material may be formed on or over inner surfaces of the tunnel dielectric material. The dielectric fill material may be formed on or over inner surfaces of the channel material. Although the cell pillar structures 300 are shown in FIG. 6 have a generally cylindrical shape vertically extending through the preliminary stack structure 200, the disclosure is not limited and the cell pillar structures 300 may individually have a geometric configuration such as, without limitation, a frustoconical shape.

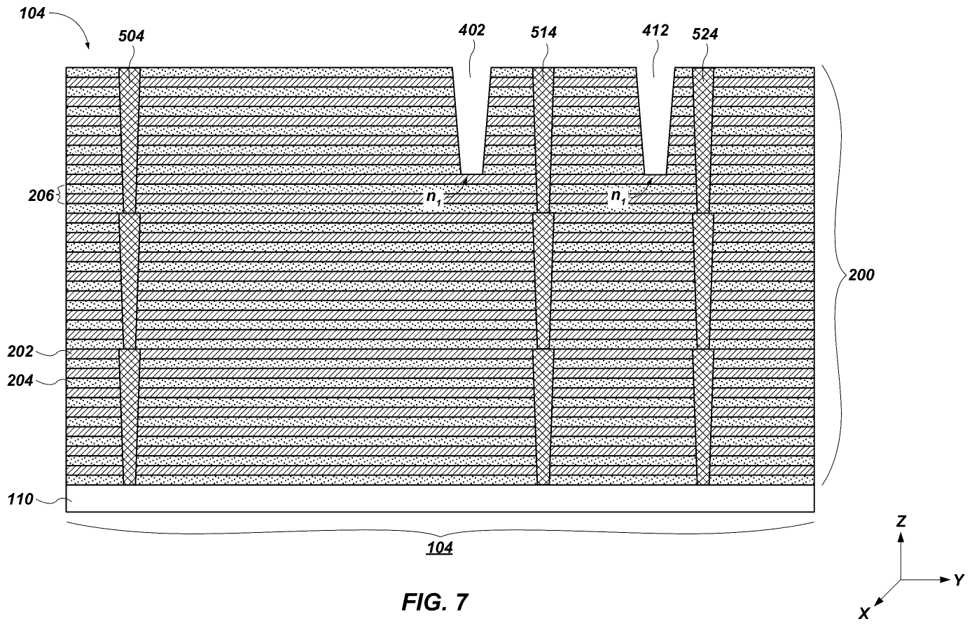

FIG. 7 through FIG. 13 are simplified, vertical cross-sectional views of the contact region 104 of the microelectronic device structure 100 at additional processing stages of the method of forming a microelectronic device of the disclosure following the processing stage previously described herein with reference to FIG. 6.

Referring to FIG. 7, the microelectronic device structure 100 is patterned (e.g., etched, in one or more material-removal acts) to form contact openings 402 and 412, individually extending vertically through an upper portion of the preliminary stack structure 200 to terminate at a tier 206 at a first elevation n₁ within the preliminary stack structure 200.

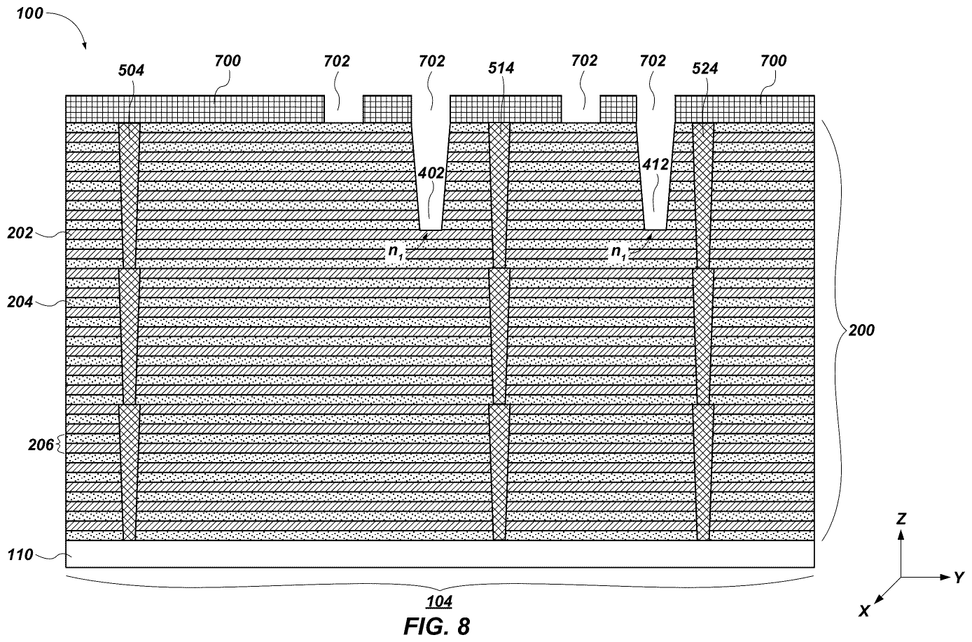

Referring to FIG. 8, a patterned mask 700 having a pattern of openings 702 therein is provided over the microelectronic device structure 100. Some of the openings 702 of the patterned mask 700 are respectively horizontally aligned (e.g., in the X-direction, in the Y-direction) with one of the contact openings 402 within the preliminary stack structure 200. Others of the openings 702 of the patterned mask 700 are respectively horizontally aligned (e.g., in the X-direction, in the Y-direction) with one of the contact openings 412 within the preliminary stack structure 200. Still others of the openings 702 of the patterned mask 700 are respectively horizontally offset (e.g., in at least the Y-direction) from all of the contact openings 402 and 412 within the preliminary stack structure 200.

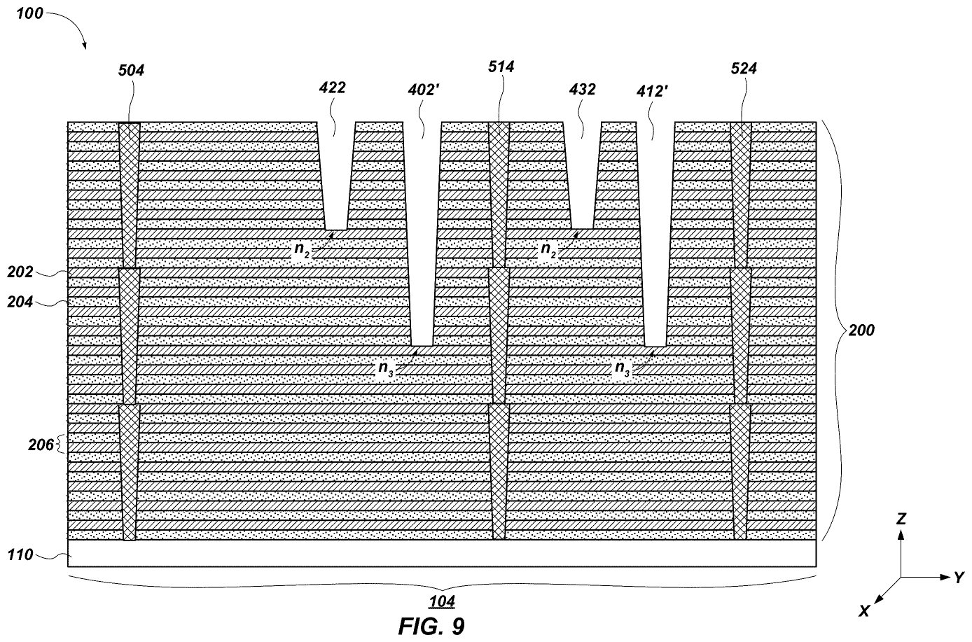

Referring next to FIG. 9, the microelectronic device structure 100 is subjected to any additional material removal (e.g., etching) process to remove portions of the insulative material and the sacrificial material 204 of the tiers 206 of the preliminary stack structure 200 within horizontal areas of openings 702 of the patterned mask 700. Contact openings 422 and 432 may be formed to extend vertically through an upper portion of the preliminary stack structure 200 to terminate at the second elevation n₂ of the preliminary stack structure 200. In addition, extended contact openings 402′ and 412′ may be formed from the contact openings 402 (FIGS. 8) and 412 (FIG. 8) by removing portions of the tiers 206 horizontally overlapping the contact openings 402 (FIGS. 8) and 412 (FIG. 8) and vertically underlying the first elevation n₁. Each of the extended contact openings 402′ and 412′ may extend vertically to or into relatively lower ones of the tiers 206 of the preliminary stack structure 200. The extended contact openings 402′ and 412′ may respectively terminate at a third elevation n₃ within preliminary stack structure 200 that is vertically below the first elevation n₁. The third elevation n₃ is more vertically proximate to the source structure 110 than the first elevation n₁. After the additional material removal process, the patterned mask 700 (FIG. 8) may be removed.

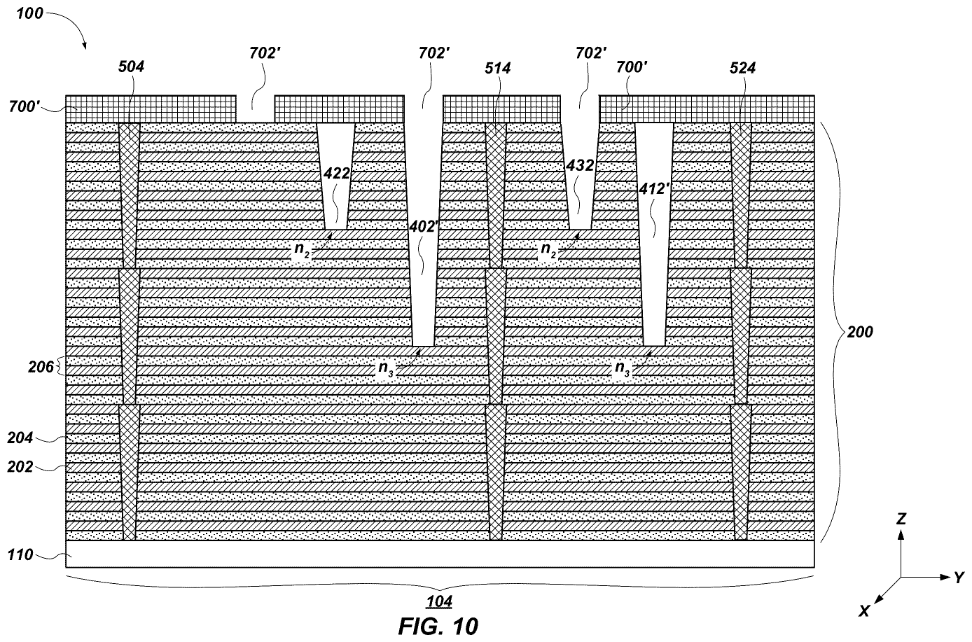

Referring next to FIG. 10, an additional patterned mask 700′ having another pattern of openings 702′ may be provided over the preliminary stack structure 200 of the microelectronic device structure 100. Some of the openings 702′ of the additional patterned mask 700′ are respectively horizontally aligned (e.g., in the X-direction, in the Y-direction) with one of the extended contact openings 402′ within the preliminary stack structure 200. Others of the openings 702′ of the additional patterned mask 700′ are respectively horizontally aligned (e.g., in the X-direction, in the Y-direction) with the contact openings 432 within the preliminary stack structure 200. Still others of the openings 702′ of the additional patterned mask 700′ are respectively horizontally offset (e.g., in at least the Y-direction) from all of the extended contact openings 402′ and 412′ and all of the contact openings 422 and 432 within the preliminary stack structure 200.

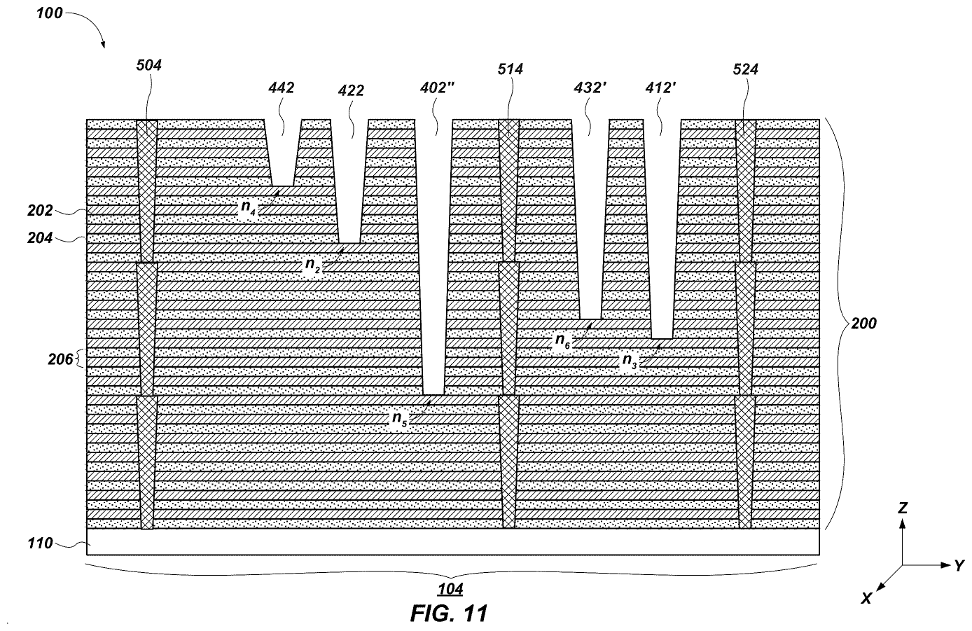

Referring to FIG. 11, the microelectronic device structure 100 may be subjected to a further material removal (e.g., etching) process to remove additional portions of the tiers 206 of the preliminary stack structure 200 within horizontal areas of the openings 702′ (FIG. 10) of the additional patterned mask 700′ (FIG. 10). The contact openings 442 may be formed to extend vertically through an upper portion of the preliminary stack structure 200 to terminate at a fourth elevation n₄ within the preliminary stack structure 200. The fourth elevation n₄ may be relatively vertically higher within the preliminary stack structure 200 than the first elevation n₁. Portions of the tiers 206 vertically underlying and within horizontal areas of the extended contact openings 402′ are removed to form further extended contact openings 402″. The further extended contact openings 402″ may respectively vertically extend relatively further into relatively lower tiers 206 of the preliminary stack structure 200 and may terminate at fifth elevation n₅ within the preliminary stack structure 200. The fifth elevation n₅ is more proximate to the source structure 110 than is the third elevation n₃. In addition, portions of the tiers 206 vertically underlying and within horizontal areas of the contact openings 432 are removed to form extended contact openings 432′. The extended contact openings 432′ may respectively vertically extend further into relatively lower ones of the tiers 206 of the preliminary stack structure 200 and may terminate at sixth elevation n₆. Each of the third elevation n₃ and the fifth elevation n₅ may be relatively vertically lower within the preliminary stack structure 200 than the sixth elevation n₆. The openings 702′ of the additional patterned mask 700′ are horizontally offset from the contact openings 422 and the extended contact openings 412′, and so the contact openings 422 and the extended contact openings 412′ are substantially not affected during the further material removal. The contact openings 422 may still terminate at the second elevation n₂, and the extended contact openings 412′ may still terminate at the third elevation n₃. After the further material removal process, the additional patterned mask 700′ (FIG. 10) may be removed.

Thus, the microelectronic device structure 100 at the processing stage of FIG. 10 may include the contact openings 442 terminated at the fourth elevation n₄, the contact openings 422 terminated at the second elevation n₂, the further extended contact openings 402″ terminated at the fifth elevation n₅, the extended contact openings 432′ terminated at the sixth elevation n₆, and the extended contact openings 412′ terminated at the third elevation n₃ of the tiers 206 of the preliminary stack structure 200. Through the processing acts described with reference to FIGS. 7 through 11, contact openings (e.g., the contact openings 442, the contact openings 422, the further extended contact openings 402″, the extended contact openings 432′, the further extended contact openings 402″) having different vertical depths than one another may be formed within the preliminary stack structure 200.

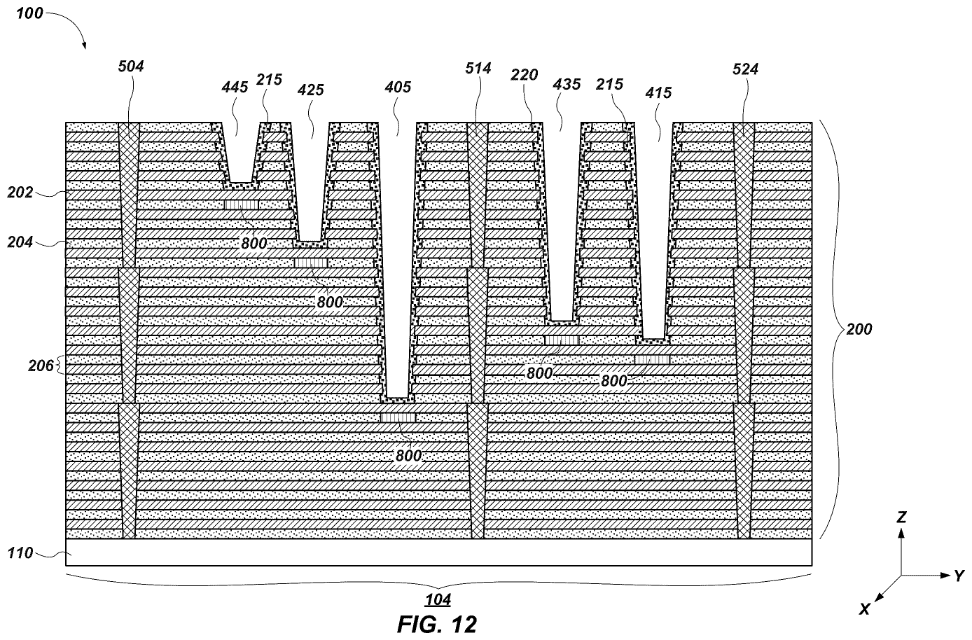

Referring next to FIG. 12, the preliminary stack structure 200 of the microelectronic device structure 100 may be subjected to an etching process that selectively removes sacrificial material 204 of the tiers 206 relative to the insulative material 202 of the tiers 206. Portions of the sacrificial material 204 of the tier 206 exposed by the contact openings 442 (FIG. 11), the contact openings 422 (FIG. 11), the further extended contact openings 402″ (FIG. 11), the extended contact openings 432′ (FIG. 11), the further extended contact openings 402″ (FIG. 11) (hereinafter collectively referred to as the “contact openings 442, 422, 402″, 432′, 412′” (FIG. 11)) may be selectively removed to form horizontal recesses 215 at vertical positions of the sacrificial material 204 of the tier 206. The sacrificial material 204 of the tiers 206 exposed by the contact openings 442, 422, 402″, 432′, 412′ (FIG. 11) may be selectively recessed back relative to the insulative material 202 of the tiers 206 exposed by the contact openings 442, 422, 402″, 432′, 412′ (FIG. 11). Thereafter, a liner material 220 may be conformally formed within the contact openings 442, 422, 402″, 432′, 412′ (FIG. 11) and the recesses 215 associated therewith to form lined contact openings 445, 425, 405, 435, 415, respectively. The liner material 220 may be formed of and include dielectric material, such as dielectric oxide material (e.g., one or more of SiOₓ, AlOₓ, HfOₓ, NbOₓ, TiOₓ, ZrOₓ, and MgOₓ). A material composition of the liner material 220 may be selected such that the sacrificial material 204 of the tiers 206 of the preliminary stack structure 200 may be selectively removed relative to the liner material 220. In additional embodiments, the recess 215 formation as shown in FIG. 11 is omitted, and the lined contact openings 445, 425, 405, 435, 415 may respectively be formed to have substantially planar outer horizontal boundaries.

Optionally, as shown in FIG. 12, the microelectronic device structure 100 may be subjected to a carbon ion implantation process before and/or after the formation of the liner material 220 within the contact openings 442, 422, 402″, 432′, 412′ (FIG. 11). The carbon ions may be implanted into the sacrificial material 204 of tiers 206 underlying and most proximate to the respective contact openings 442, 422, 402″, 432′, 412′ (FIG. 11) to form carbon ion-implanted structures 800. Each of the carbon ion-implanted structures 800 may vertically underlie and at least partially horizontally overlap (e.g., may be substantially horizontally aligned with) a respective one of the contact opening 442, 422, 402″, 432′, 412′ (FIG. 11).

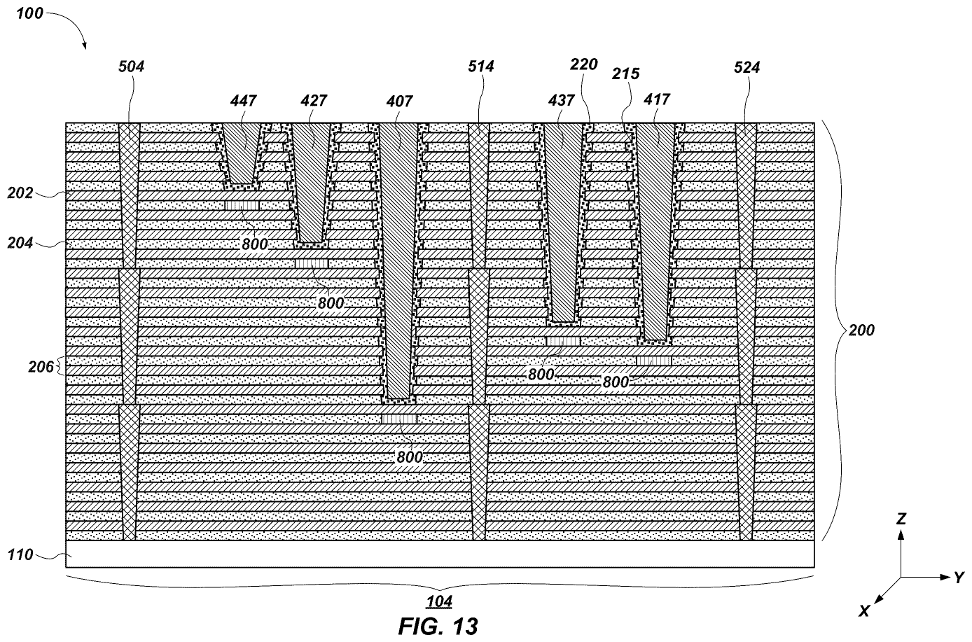

Referring to FIG. 13, the lined contact openings 445, 425, 405, 435, 415 (FIG. 11) may respectively be substantially filled with a third sacrificial material to form sacrificially filled contact openings 447, 427, 407, 437, 417, respectively. A material composition of the third sacrificial material may be selected such that the sacrificial material 204 of the tiers 206 of the preliminary stack structure 200 and the first sacrificial material of the sacrificially filled inter-block openings 504, 514, 524 may be selectively removed (e.g., selectively etched) relative to the third sacrificial material.

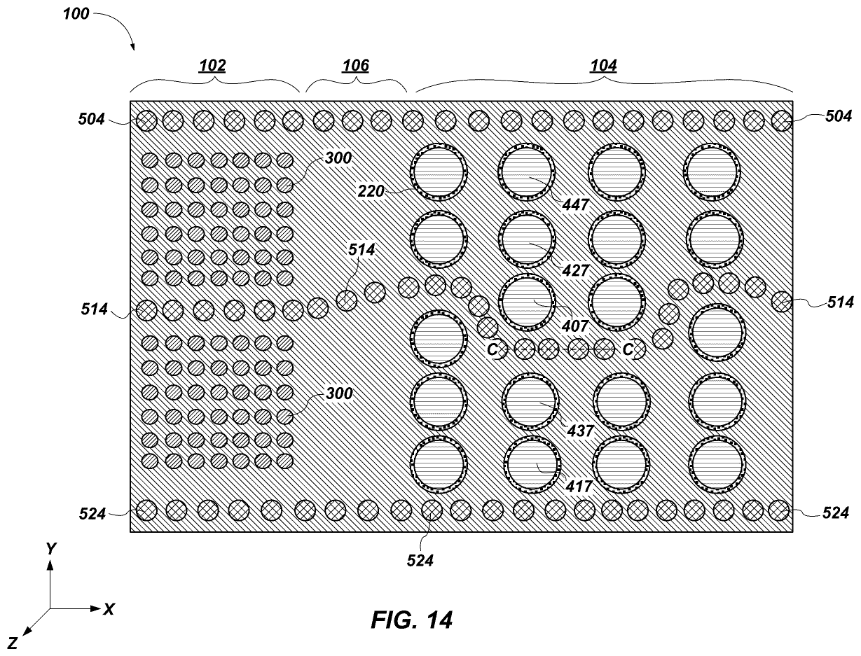

FIG. 14 shows a schematic, top-down view of a portion of the microelectronic device structure 100 at the processing stage of FIG. 13. As shown in FIG. 14, the microelectronic device structure 100 includes the array region 102 shown in and described with reference to FIG. 6, the contact region 104 shown in and described with reference to FIG. 13, and the connecting region 106 positioned horizontally between the array region 102 and the contact region 104. In the array region 102, the cell pillar structures 300 are arranged in rows respectively horizontally extending in the X-direction and columns respectively horizontally extending in the Y-direction. In the contact region 104, the sacrificially filled contact openings 447, 427, 407, 437, 417, including the associated liner material 220, are arranged in different rows horizontally extending in the X-direction and different columns respectively horizontally extending in the Y-direction. The microelectronic device structure 100 is also formed to include different groups of the sacrificially filled inter-block openings 504, 514, 524 (e.g., a group of the sacrificially filled inter-block openings 504, a group of the sacrificially filled inter-block openings 514, and a group of the sacrificially filled inter-block openings 524). A group of the sacrificially filled inter-block openings 514 may be horizontally positioned, in the Y-direction, between the group of the sacrificially filled inter-block openings 504 and the group of the sacrificially filled inter-block openings 524. The group of the sacrificially filled inter-block openings 504 are arranged in a substantially linear pattern (e.g., a row) horizontally extending, in the X-direction, through the array region 102, the connecting region 106, and the contact region 104 of the microelectronic device structure 100. The group of the sacrificially filled inter-block openings 514 are arranged in a partially non-linear pattern horizontally extending in the X-direction and in the Y-direction. The partially non-linear pattern of the group of the sacrificially filled inter-block openings 514 may be substantially linear (e.g., in the X-direction) within the array region 102, and may be at least partially non-linear (e.g., wavy, winding, curving) extending through the contact region 104 and the connecting region 106 of the microelectronic device structure 100. The group of the sacrificially filled inter-block openings 524 are in a substantially linear pattern (e.g., a row) horizontally extending, in the X-direction, through the array region 102, the connecting region 106, and the contact region 104 of the microelectronic device structure 100.

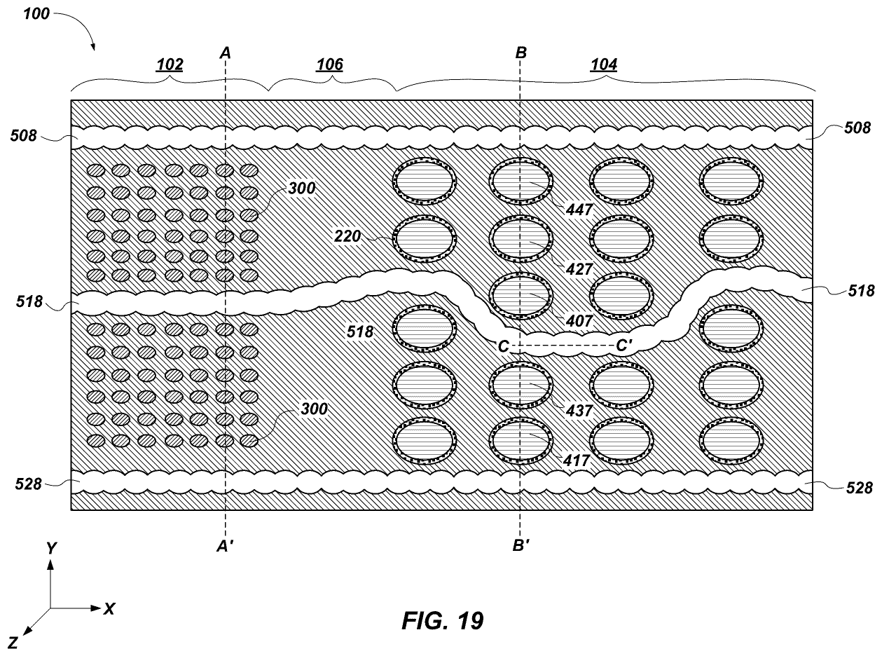

As will be described herein, the patterns of the groups of the inter-block openings 504, 514, 524 respectively may partially define shapes for relatively larger openings (e.g., block isolation slots) to be formed and utilized to form block isolation structures of the microelectronic device structure 100. For instance, the pattern of the group of inter-block openings 514 may, in further processing stages, at least partially define a partially non-linear shape for a block isolation slot 518 (FIG. 19) of the microelectronic device structure 100.

The first sacrificial material of the sacrificially filled inter-block openings 504, 514, 524 in the array region 102 may be removed from the microelectronic device structure 100 at the time and/or using the same process as the first sacrificial material of the sacrificially filled inter-block openings 504, 514, 524 in the contact region 104 being removed from the microelectronic device structure 100.

FIG. 15 through FIG. 18 are simplified, vertical cross-sectional views of the microelectronic device structure 100, taken along the dashed line C-C of FIG. 14, at different processing stages of the method of forming a microelectronic device of the disclosure. The process stage of FIG. 15 may follow the processing stage previously described with reference to FIGS. 13 and 14. FIG. 15 through FIG. 18 illustrate the process of removing the first sacrificial material from the sacrificially filled inter-block openings 514, and ultimately forming the block isolation slot 518 (FIG. 19).

FIG. 15 through FIG. 18 depict five inter-block openings 514 within the overall group of the inter-block openings 514 for ease and simplicity in understanding the drawings and associated description. However, a different number of the inter-block openings 514 may be included within the horizontal span of the vertical cross-section shown in FIG. 15 through FIG. 18, as desired.

Referring to FIG. 15, a mask material 704 is formed over the top surface of the preliminary stack structure 200, and the mask material 704 may be patterned to form patterned openings 706 at least partially (e.g., substantially) horizontally overlapping the sacrificially filled inter-block openings 514. In some embodiments, a photoresist material is formed on or over the mask material 704, is patterned (e.g., photo exposed and developed), and the resulting openings formed in the patterned photoresist material are extended into the mask material 704 to form the patterned openings 706. The mask material 704 may be removed during subsequent processing stages. The mask material 704 may be formed of and include a material having different etch selectively than the first sacrificial material of the sacrificially filled inter-block openings 514 during mutual exposure to an etchant. In some embodiments, the mask material 704 is formed of and includes dielectric material, such as dielectric nitride material (e.g., silicide nitride).

Referring to FIG. 16, the mask material 704 and the patterned openings 706 therein may be employed to remove the first sacrificial material within the sacrificially filled inter-block openings 514 through one or more etch processes (e.g., an anisotropic etching process) that selectively remove exposed portions of the first sacrificial material without substantially removing portions of the insulative material 202 and the sacrificial material 204 of the tiers 206. The first sacrificial material within the sacrificially filled inter-block openings 514 of each of the preliminary deck structure 200′, the additional preliminary deck structure 200″, and the further preliminary deck structure 200″′ may be removed to form inter-block openings 516 vertically extending through the preliminary deck structures 200′, 200″, 200″′. In some embodiments, a lateral dimension of respective ones of the inter-block openings 516 is within a range of from about 100 nm to about 200 nm.

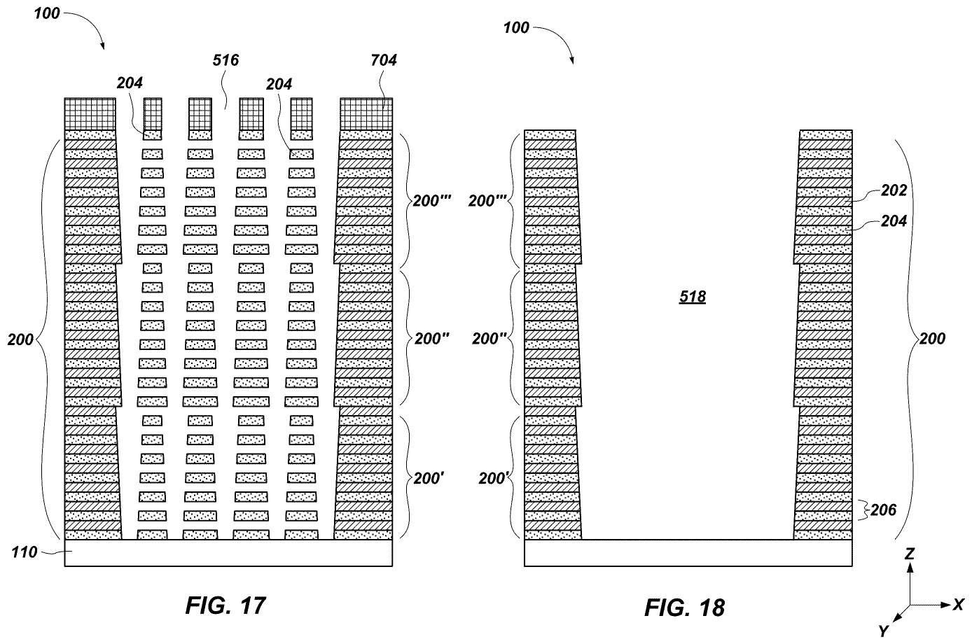

Referring to FIG. 17, portions of the insulative material 202 (FIG. 16) of the tier 206 horizontally interposed between the inter-block openings 516 (e.g., interposed between the inter-block openings 516 in the X-direction and/or Y-direction) may be removed (e.g., exhumed). For example, the portions of the insulative material 202 may be removed, by way of the inter-block openings 516, using an etching process (e.g., isotropic etching process) that selectively removes exposed portions of the insulative material 202 (e.g., oxide material) without substantially removing portions of the sacrificial material 204 (e.g., nitride material). The removal process may effectively join the inter-block openings 516 together by removing the portions of the insulative material 202 (FIG. 16) previously intervening horizontally between and separating the inter-block openings 516. In some embodiments, the portions of the insulative material 202 are removed using an oxide recess etching process. In some embodiments, portions of the insulative material 202 of the tiers 206 of each of the first preliminary deck structure 200′, the additional preliminary deck structure 200″, and the further preliminary deck structure 200″′ are removed substantially simultaneously by way of the inter-block openings 516.

Referring to FIG. 18, the portions of the sacrificial material 204 (FIG. 17) of the tiers 206 horizontally interposed between the inter-block openings 516 (FIG. 17) may be removed to form a block isolation slot 518. By way of non-limiting example, the portions of the sacrificial material 204 may be removed by exposing the sacrificial material 204 to an etchant (e.g., a wet etchant) including one or more of phosphoric acid, sulfuric acid, hydrochloric acid, nitric acid, or another material. In some embodiments, the sacrificial material 204 is removed by exposing the sacrificial material 204 to a so-called “wet nitride strip” comprising phosphoric acid. In some embodiments, the portions of the sacrificial material 204 of each of the first preliminary deck structure 200′, the additional preliminary deck structure 200″, and the further preliminary deck structure 200″′ are removed substantially simultaneously. In some embodiments, remaining portions of the mask material 704 are then removed by way of a CMP process.

As is shown in FIG. 18, by removing the portions of the insulative material 202 (FIG. 15) and the sacrificial material 204 (FIG. 18) horizontally interposed between the sacrificially filled inter-block openings 514 (FIG. 15), the inter-block openings 516 (FIG. 17) may be substantially merged together to form the block isolation slot 518. The block isolation slot 518 may extend vertically through the preliminary deck structure 200′, the additional preliminary deck structure 200″, and the further preliminary deck structure 200″′. The block isolation slot 518 may horizontally extend through the preliminary stack structure 200 in an at least partially non-linear path. The block isolation slot 518 may be utilized to form the block isolation structure 510 previously described herein with reference to FIG. 2.

FIG. 19 shows a schematic top-down view of a portion of a microelectronic device structure 100 after the process stage described with reference to FIG. 18. As shown in FIG. 19, the block isolation slot 518 extends horizontally through each of the array region 102, the connecting region 106, and the contact region 104 of the microelectronic device structure 100. A portion of the block isolation slot 518 within the array region 102 may horizontally extend (e.g., in the X-direction) in a substantially linear path. An additional portion of the block isolation slot 518 within the contact region 104 may horizontally extend (e.g., in the X-direction and the Y-direction) in a non-linear path. A further portion of the block isolation slot 518 within the connecting region 106 may horizontally extend (e.g., in the X-direction and the Y-direction) from and between the portion within the array region 102 and the additional portion within the contact region 104 in a further, substantially linear path.

Still referring to FIG. 19, another block isolation slot 508 may be formed by merging the group of the sacrificially filled inter-block openings 504 (FIGS. 13 and 14) using the process described with reference to FIG. 15 to FIG. 18. Since the group of sacrificially filled inter-block openings 504 exhibits a straight line pattern horizontally extending (e.g., in the X-direction) through the array region 102, the contact region 104, and the connecting region 106 of the preliminary stack structure 200, the formed block isolation slot 508 may horizontally extend (e.g., in the X-direction) in a substantially linear path through the array region 102, the contact region 104, and the connecting region 106 of the preliminary stack structure 200. In addition, a further block isolation slot 528 may be formed by merging the group of the sacrificially filled inter-block openings 524 using the process described with reference to FIG. 15 to FIG. 18. Since the group of sacrificially filled inter-block openings 524 exhibits a straight line pattern horizontally extending (e.g., in the X-direction) through the array region 102, the contact region 104, and the connecting region 106 of the preliminary stack structure 200, the formed block isolation slot 528 may horizontally extend (e.g., in the X-direction) in a substantially linear path through the array region 102, the contact region 104, and the connecting region 106 of the preliminary stack structure 200. As shown in FIG. 19, the block isolation slot 518 may be horizontally interposed, in the Y-direction, between the another block isolation slot 508 and the further block isolation slot 528. The block isolation slot 518, the another block isolation slot 508, and the further block isolation slot 528 are collectively referred to herein as the block isolation slots 518, 508, 528, and may be used to form the block isolation structures 510, 500, 520 previously described herein with reference to FIG. 2, respectively.

In some embodiments, a pitch between horizontal centers of horizontally neighboring sacrificially filled inter-block openings to be merged into a respective block isolation slot is substantially constant (e.g., substantially uniform) throughout regions within the preliminary stack structure 200 to become substantially linear portions of a formed block isolation slot. For example, the pitch between horizontal centers of horizontally neighboring sacrificially filled inter-block openings 514 (FIG. 14) may be substantially constant within the array region 102 of the preliminary stack structure 200, where the horizontally neighboring sacrificially filled inter-block openings 514 (FIG. 14) are merged together to form a substantially linear portion of the block isolation slot 518.

In some embodiments, the pitch between horizontal centers of horizontally neighboring sacrificially filled inter-block openings to be merged into a respective block isolation slot is substantially constant (e.g., substantially uniform) throughout regions within the preliminary stack structure 200 to become non-linear portions of a formed block isolation slot. For example, the pitch between horizontal centers of horizontally neighboring sacrificially filled inter-block openings 514 may be substantially constant within the contact region 104 of the preliminary stack structure 200, where the horizontally neighboring sacrificially filled inter-block openings 514 (FIG. 14) are merged together to form a non-linear portion of the block isolation slot 518.

In some embodiments, the pitch between horizontal centers of horizontally neighboring sacrificially filled inter-block openings to be merged into a respective block isolation slot is substantially constant (e.g., substantially uniform) throughout each of the regions within the preliminary stack structure 200 to become substantially linear portions of a formed block isolation slot as well as additional regions within the preliminary stack structure 200 to become non-linear portions of the formed block isolation slot. For example, the pitch between horizontal centers of horizontally neighboring sacrificially filled inter-block openings 514 may be substantially constant within each of the array region 102 (where horizontally neighboring sacrificially filled inter-block openings 514 (FIG. 14) are merged together to form a substantially linear portion of the block isolation slot 518), the contact region 104 (where additional horizontally neighboring sacrificially filled inter-block openings 514 (FIG. 14) are merged together to form a non-linear portion of the block isolation slot 518), and the connecting region 106 (where further horizontally neighboring sacrificially filled inter-block openings 514 (FIG. 14) are merged together to form another substantially linear portion of the block isolation slot 518).

FIG. 20A is a simplified, vertical cross-sectional view taken along the dashed line A-A′ of FIG. 19 in the array region 102. FIG. 20B is a simplified, vertical cross-sectional view taken along the dashed line B-B′ of FIG. 19 in the contact region 104. The block isolation slots 508, 518, 528 shown in each of FIG. 20A and FIG. 20B serve as replacement gate slots for the so-called “replacement gate process,” as described below.

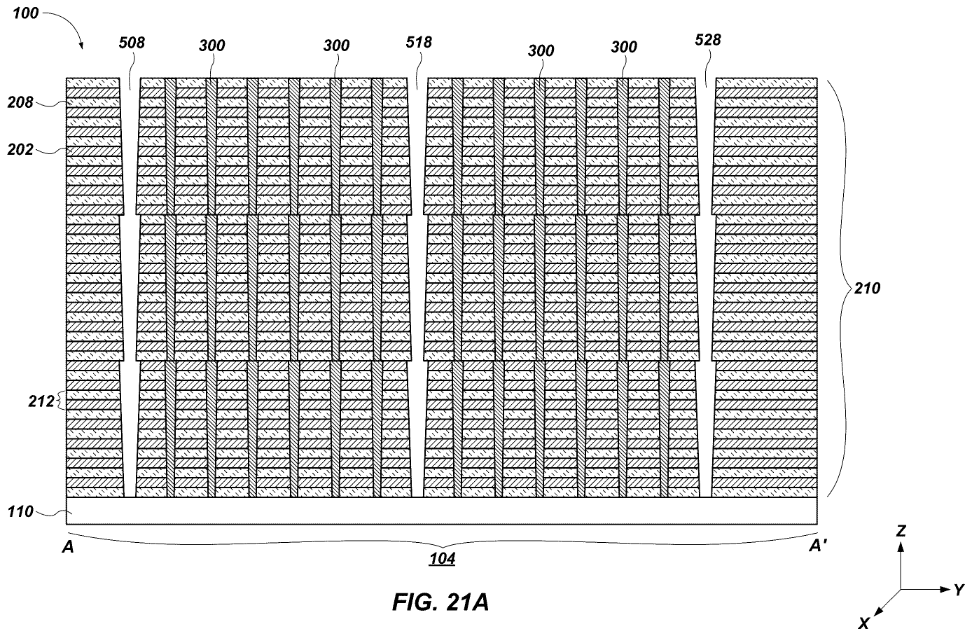

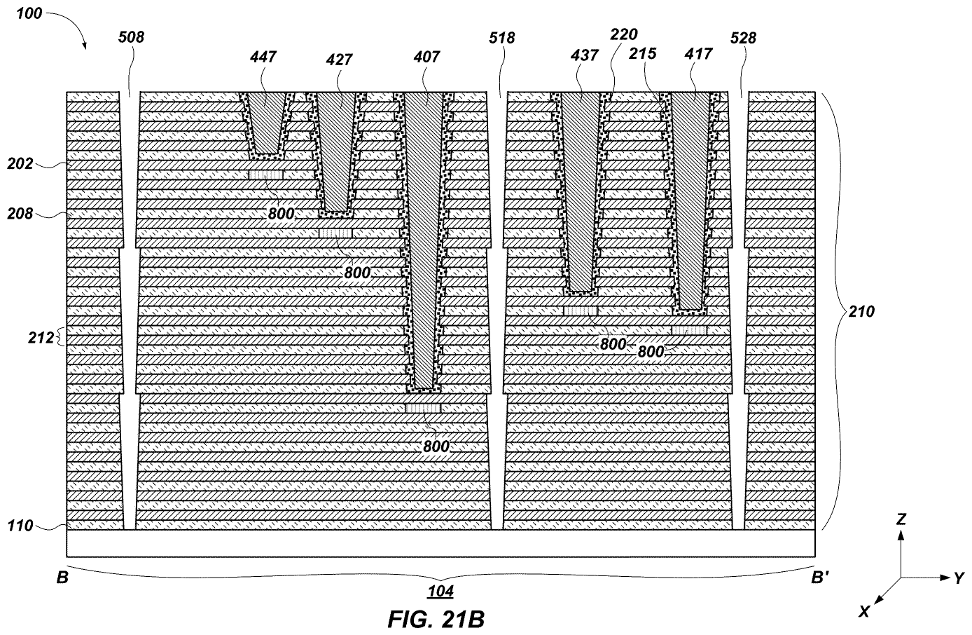

FIG. 21A is a simplified, vertical cross-sectional view taken along the dashed line A-A′ within the array region 102, at a processing stage following that previously described with reference to FIGS. 19, 20A, and 20B. FIG. 21B is a simplified, vertical cross-sectional view taken along the dashed line B-B′ within the contact region 104, at the same processing stage as that of FIG. 21A.

Referring collectively to FIG. 21A and FIG. 21B, the microelectronic device structure 100 is subjected to material removal process (e.g., a stripping process, such as a wet nitride stripping process) to selectively remove the sacrificial material 204 (FIGS. 20A and 20B) of the tiers 206 (FIGS. 20A and 20B) relative to the insulative material 202 of the tiers 206 (FIGS. 20A and 20B). As a non-limiting example, when the insulative material 202 includes SiO₂ and the sacrificial material 204 includes Si₃N₄, the sacrificial material 204 may be selectively removed using phosphoric acid as an etchant. The removal of the sacrificial material 204 of the tiers 206 (FIGS. 20A and 20B) effectuates the formation of voids vertically alternating with the remaining portions of the insulative material 202 of the tiers 206 (FIGS. 20A and 20B). Thereafter, the voids may be substantially filled with conductive material 208 to form a stack structure 210. The stack structure 210 may include a vertically alternating sequence of the insulative material 202 and the conductive material 208 arranged in tiers 212. Each of the tiers 212 may include a level of the insulative material 202 vertically neighboring (e.g., vertically adjacent to) a level of the conductive material 208. The conductive material 208 of some of the tiers 212 may serve as local word line structures for a subsequential formed microelectronic device (e.g., memory device, such as a 3D NAND Flash memory device). The conductive material 208 of some others of the tiers 212 may serve as select gate structures, such as select gate drain (SGD) structures and select gate source (SGS) structures of the subsequential formed microelectronic device. The microelectronic device structure 100 includes the cell pillar structures 300 extending vertically through the stack structure 210 within the array region 102 (FIG. 21A); and the sacrificially filled contact openings 447, 427, 407, 437, 417 extending vertically through the stack structure 210 within the contact region 104 (FIG. 21B).

In some embodiments, the conductive material 208 is formed of and includes one or more of tungsten (W), tantalum nitride (TaN), and titanium nitride (TiN). In additional embodiments, the conductive material 208 is formed of and includes a Mo-containing material. In some embodiments, the conductive material 208 is substantially free of silicon. In some embodiments, the conductive material 208 is formed of a single (e.g., only one) material (e.g., only one elemental metal, only one single metal-containing material). In some other embodiments, the conductive material 208 is formed of and includes multiple materials (e.g., multiple elemental metals, multiple metal-containing materials).

Intersections of the cell pillar structures 300 and some of the conductive material 208 of some of the tiers 212 of the stack structure 210 form vertically extending strings of memory cells for the microelectronic device structure 100 (and, hence, a microelectronic device formed to include the microelectronic device structure 100). In some embodiments, the memory cells may be so-called “charge-trapping” memory cells. For example, the memory cells may be so-called “MONOS” (metal-oxide-nitride-oxide-semiconductor) memory cells, or more specifically, may be so-called “TANOS” (tantalum nitride-aluminum oxide-nitride oxide-semiconductor) memory cells, or so-called “BETANOS” (band/barrier engineered TANOS) memory cells, each of which are subsets of MONOS memory cells. In further embodiments, the memory cells comprise so-called “floating gate” memory cells including floating gates (e.g., metallic floating gates) as charge storage structures.

In some embodiments, an additional liner material may be formed (e.g., substantially continuously formed) on exposed surfaces defining boundaries of the voids, such as on exposed surfaces of the insulative material 202 and charge-blocking material of the cell pillar structures 300 prior to the formation of the conductive material 208. The conductive material 208 may then be formed to substantially fill remaining portions of the voids unoccupied by the additional liner material. In some embodiments, the additional liner material is a conductive liner material formed of and including a seed material from which the conductive material 208 may be formed. The conductive liner material may be formed of and include, for example, a metal (e.g., titanium, tantalum), a metal nitride (e.g., tungsten nitride, titanium nitride, tantalum nitride), or another material. In some embodiments, the conductive liner material comprises titanium nitride. In additional embodiments, the liner material is a dielectric liner material formed of and included any conventional dielectric materials or high-K dielectric materials.

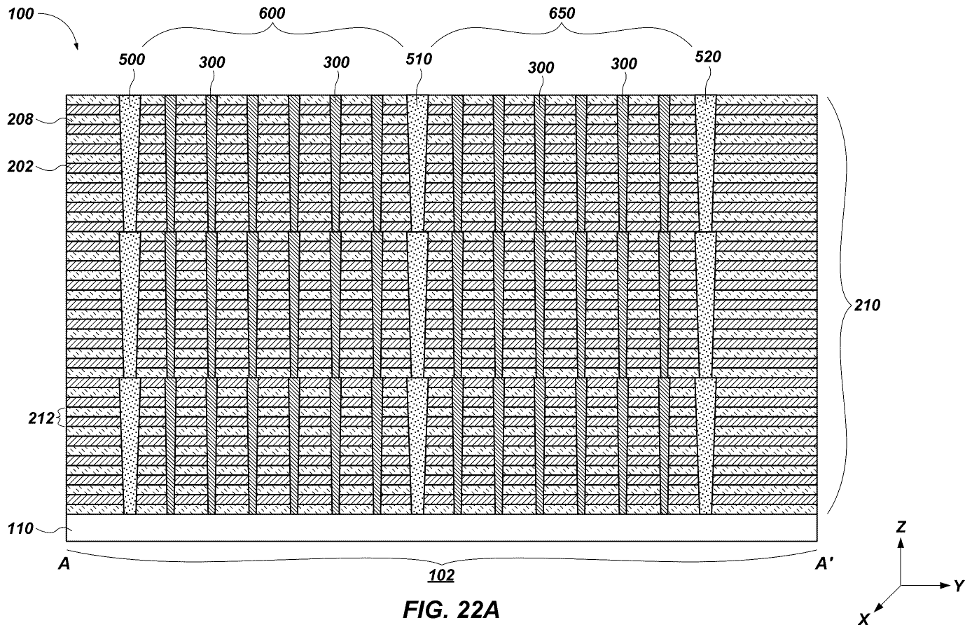

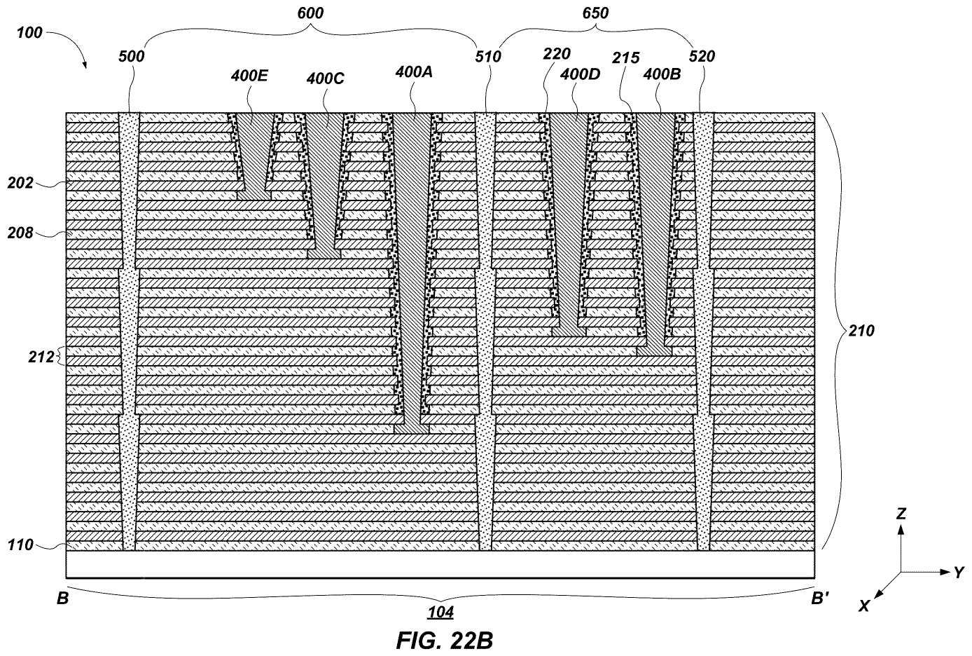

FIG. 22A is a simplified, vertical cross-sectional view taken along the dashed line A-A′ within the array region 102, at a processing stage following that previously described with reference to FIGS. 21A and 21B. FIG. 22B is a simplified, vertical cross-sectional view taken along the dashed line B-B′ within the contact region 104, at the same processing stage as that of FIG. 22A.

Referring collectively to FIGS. 22A and 22B, the block isolation slots 508, 518, 528 (FIGS. 21A and 21B) may be filled with dielectric material to form the block isolation structures 500, 510, 520, respectively. For example, the block isolation structures 500, 510, 520 may respectively be formed to include dielectric oxide material (e.g., silicon dioxide). The block isolation structures 500, 510, 520 respectively vertically extend through the stack structure 210 and may divide (e.g., partition) the stack structure 210 into a plurality of blocks separated from one another by at least one of the block isolation structures 500, 510, 520. For example, the block isolation structure 510 is formed to horizontally intervene (e.g., in the Y-direction) and separate the block 600 and the block 650. A lateral dimension, in the Y-direction, of one or more of the block isolation structures 500, 510, 520 may be relatively larger than a lateral dimension, in the Y-direction, of one or more (e.g., each) of the cell pillar structures 300.

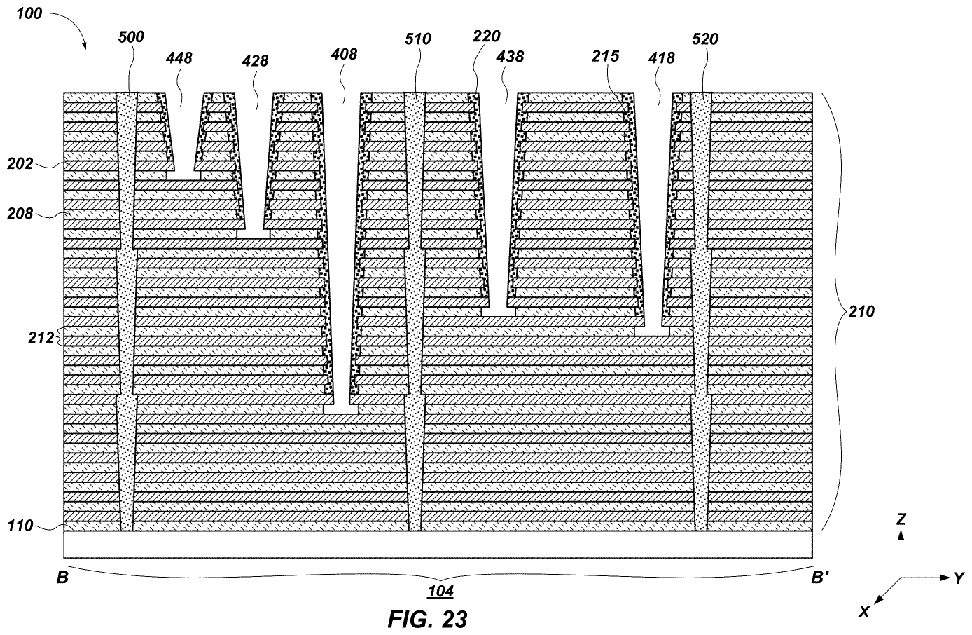

FIG. 23 is a simplified, vertical cross-sectional view taken along the dashed line B-B′ within the contact region 104, at a processing stage following that previously described with reference to FIGS. 22A and 22B. Referring to FIG. 23, the microelectronic device structure 100 is subjected to a material removal process to selectively remove the third sacrificial material within the sacrificially filled contact openings 447, 427, 407, 437, 417 (FIG. 21B) and the carbon implanted structures 800 (FIG. 21B) thereunder. In some embodiments, a first material removal process is employed to selectively remove the third sacrificial material, a so-called “punch-through” etch is then employed to remove portions of the liner material 220 and the insulative material 202 vertically overlying and within horizontal areas of carbon implanted structures 800, and then the carbon implanted structures 800 are selectively removed using a further material removal process. As a result, the contact openings 448, 428, 408, 438, 418 are formed to respectively vertically extend further into the relatively lower tiers 212 of the stack structure 210.

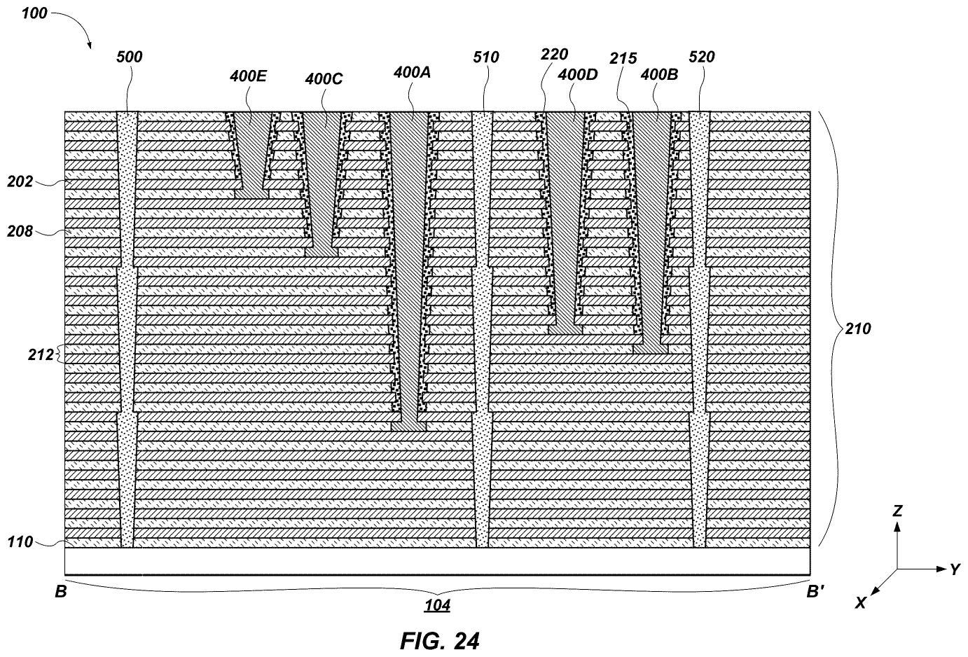

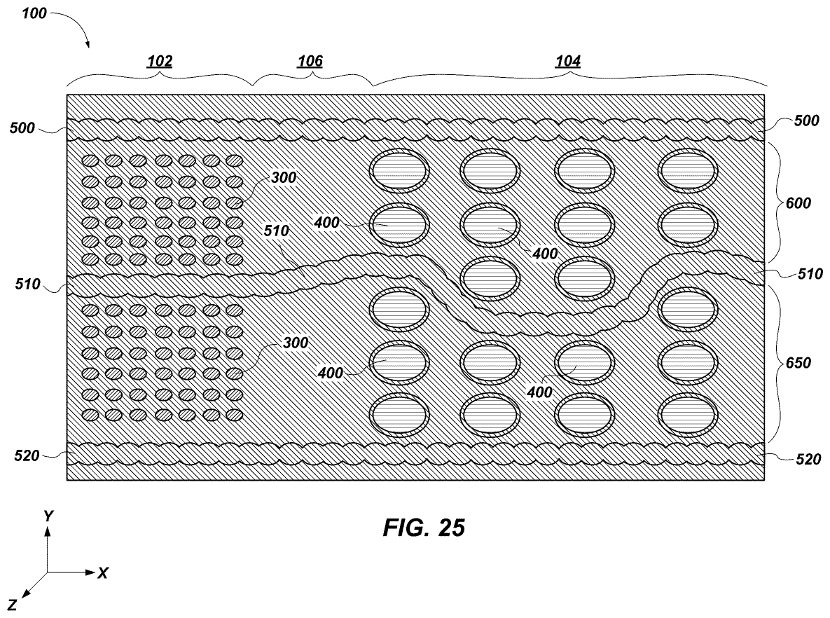

FIG. 24 is a simplified, vertical cross-sectional view taken along the dashed line B-B′ within the contact region 104, at a processing stage following that previously described with reference to FIG. 23. FIG. 25 shows a schematic top-down view of a portion of a microelectronic device structure 100 of FIG. 24.

Referring to FIG. 24, the contact openings 448, 428, 408, 438, 418 (FIG. 23) are substantially filled with conductive material to form conductive contact structures 400E, 400C, 400A, 400D, 400B, respectively. These conductive contact structures 400E, 400C, 400A, 400D, 400B are collectively shown as the conductive contact structures 400 in FIG. 2. The conductive contact structures 400 respectively contact a level of the conductive material 208 of one of the tiers 212 of the stack structure 210. The conductive contact structures 400 may be employed to couple the conductive material 208 of respective ones of the tiers 212 to control logic.

In some embodiments, a lateral dimension of an individual conductive contact structure 400 is within a range of from about 600 nanometers (nm) to about 700 nm. In addition, in some embodiments, a pitch between horizontally neighboring conductive contact structures 400 in at least one horizontal direction (e.g., the Y-direction) is less than about 500 nm.

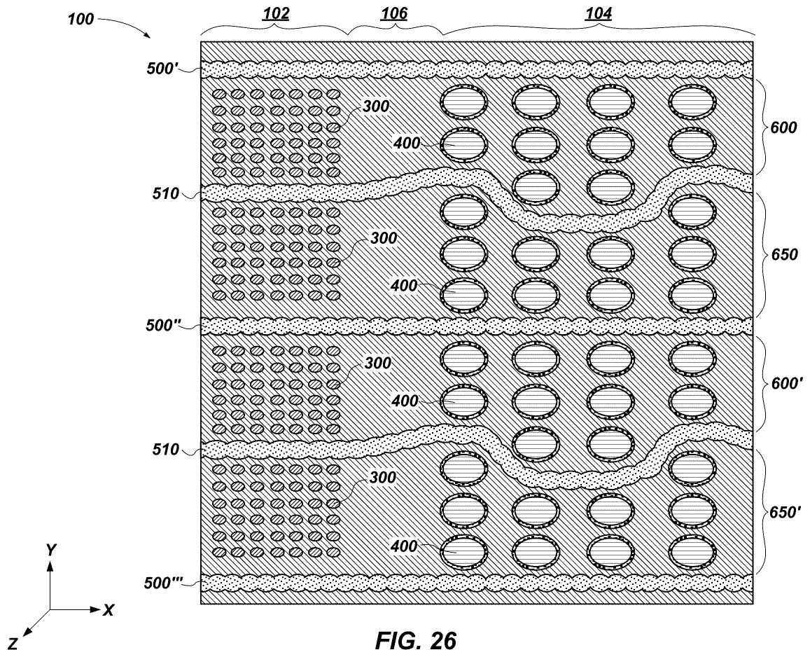

FIG. 26 shows a schematic top-down view of a portion of a microelectronic device structure 100, according to some embodiments of the disclosure. The microelectronic device structure 100 is formed to include the array region 102, the connecting region 106 horizontally adjacent (e.g., in X-direction) to the array region 102, and the contact region 104 horizontally adjacent (e.g., in X-direction) to the connecting region 106. The microelectronic device structure 100 is also formed to include block isolation structures 500′, 510, 500″, 510′, 500″′ respectively vertically extending completely through a stack structure (e.g., the stack structure 210 (FIG. 24)) of the microelectronic device structure 100, and extending horizontally through the array region 102, the connecting region 106, and the contact region 104. The block isolation structure 500′, the block isolation structure 500″, and the block isolation structure 500″′ horizontally extend in parallel with one another in the X-direction, in substantially linear paths. The block isolation structure 510 is horizontally positioned between the block isolation structure 500′ and the block isolation structures 500″, and between block 600 and block 650 in the Y-direction. The block isolation structure 510 horizontally extends (e.g., in the X-direction) in a substantially linear path through the array region 102, and horizontally extends (e.g., in the X-direction and the Y-direction) through the contact region 104 in a non-linear (e.g., curved, waived, weaving) path. The block isolation structure 510′ is positioned between the block isolation structure 500″ and the block isolation structures 500″′, and between block 600′ and block 650′ in the Y-direction. The block isolation structure 510′ horizontally extends (e.g., in the X-direction) in a substantially linear path through the array region 102, and horizontally extends (e.g., in the X-direction and the Y-direction) through the contact region 104 in a non-linear (e.g., curved, waived, weaving) path. The block isolation structure 510′ may horizontally extend in parallel with the block isolation structure 510.

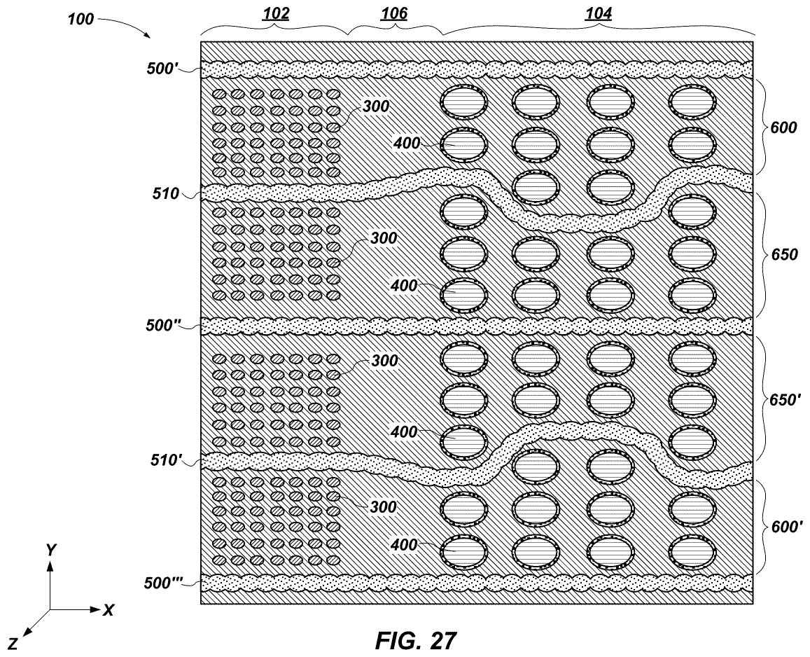

FIG. 27 shows a schematic top-down view of a portion of a microelectronic device structure 100, according to some additional embodiments of the disclosure. The microelectronic device structure 100 is formed to include the array region 102, the connecting region 106 horizontally adjacent (e.g., in X-direction) to the array region 102, and the contact region 104 horizontally adjacent (e.g., in X-direction) to the connecting region 106. The microelectronic device structure 100 is also formed to include block isolation structures 500′, 510, 500″, 510′, 500″′ respectively vertically extending completely through a stack structure (e.g., the stack structure 210 (FIG. 24)) of the microelectronic device structure 100, and extending horizontally through the array region 102, the connecting region 106, and the contact region 104. The block isolation structures 500′, the block isolation structures 500″, and the block isolation structures 500″′ horizontally extend in parallel with one another in the X-direction, in substantially linear paths. The block isolation structure 510 is horizontally positioned between the block isolation structure 500′ and the block isolation structure 500″, and between block 600 and block 650 in the Y-direction. The block isolation structure 510 horizontally extends (e.g., in the X-direction) in a substantially linear path through the array region 102, and horizontally extends (e.g., in the X-direction and the Y-direction) through the contact region 104 in a non-linear (e.g., curved, waived, weaving) path. The block isolation structure 510′ is positioned between the block isolation structure 500″ and the block isolation structure 500″′, and between block 600′ and block 650′ in the Y-direction. The block isolation structure 510′ horizontally extends (e.g., in the X-direction) in a substantially linear path through the array region 102, and horizontally extends (e.g., in the X-direction and the Y-direction) through the contact region 104 in a non-linear (e.g., curved, waived, weaving) path. The block isolation structure 510′ may mirror the block isolation structure 510. The block isolation structure 510′ may not horizontally extend in parallel with the block isolation structure 510.

Referring collectively to FIGS. 2 and 25-27, the conductive contact structures 400 are depicted as being arranged into rows respectively including a group of the conductive contact structures 400 substantially aligned with each in the Y-direction, and into columns respectively including another group of the conductive contact structures 400 substantially aligned with each in the X-direction. However, the disclosure is not limited, and at least one of the conductive contact structures 400 may be horizontally offset relative to one another in any way desired.

Furthermore, as shown in FIGS. 2 and 25-27, a minimum width (e.g., in the Y-direction) of the block isolation structures 500 and 510 is less than a minimum width (e.g., in the Y-direction) of the conductive contact structures 400 within the contact region 104 of block 600.

Thus, in accordance with some embodiments of the disclosure, a microelectronic device includes a stack structure divided into blocks respectively. The stack structure comprises levels of conductive material vertically alternating with levels of insulative material. The stack structure includes an array region and a contact region horizontally offset from the array region in a first direction. The array region has vertically extended strings of memory cells therein. The contact region has conductive contact structures in contact with at least some of the levels of conductive material of the stack structure. The microelectronic device further includes block isolation structures vertically extending completely through the stack structure. The block isolation structures horizontally alternate with the blocks in a second direction orthogonal to the first direction. At least one of the block isolation structures includes a first portion horizontally overlapping the array region of each of two of the blocks in the first direction, and a second portion horizontally overlapping the contact region of each of the two of the blocks in the first direction. The first portion extends horizontally in a substantially linear path in the first direction. The second portion extends horizontally in a non-linear path in the first direction and the second direction.

Moreover, in accordance with embodiments of the disclosure, a method of forming a microelectronic device includes forming a preliminary stack structure to include levels of insulative material vertically alternating with levels of sacrificial material, and to include an array region and a contact region offset from the array region in a first horizontal direction. Pillar structures are formed in the array region extending vertically through the preliminary stack structure. The method also includes forming patterns of inter-block openings in the preliminary stack structure extending vertically through the stack structure and extending horizontally through the array region and the contact region. At least one of the patterns of inter-block openings include a group of the inter-block openings within the array region and an additional group of the inter-block openings within the contact region. The group of the inter-block openings is substantially linearly arranged relative to one another. The additional group of the inter-block openings is at least partially non-linearly arranged relative to one another. The method also includes merging the inter-block openings of respective ones of the patterns of inter-block openings together to form block isolation slots. The sacrificial material of the levels of sacrificial material is replaced with conductive material to form a stack structure including the levels of insulative material vertically alternating with levels of conductive material. The conductive contact structures are formed in the contact region and respectively vertically extending to one of the levels of conductive material of the stack structure.

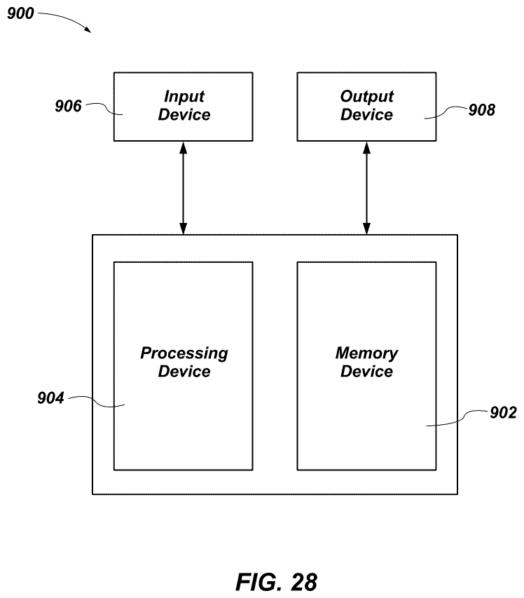

FIG. 28 is a block diagram of an electronic system 900, in accordance with embodiments of the disclosure. The electronic system 900 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 900 includes at least one memory device 902. The memory device 902 may include, for example, an embodiment of a microelectronic device structure and/or a microelectronic device previously described within with respect to one of more of FIGS. 2 and 25-27.

The electronic system 900 may further include at least one electronic signal processor device 904 (often referred to as a “microprocessor”). The electronic signal processor device 904 may, optionally, include an embodiment of a microelectronic device structure and/or a microelectronic device previously described within with respect to one of more of FIGS. 2 and 25-27. The electronic system 900 may further include one or more input devices 906 for inputting information into the electronic system 900 by a user, such as, for example, a mouse or other pointing device, a keyboard, a touchpad, a button, or a control panel. The electronic system 900 may further include one or more output devices 908 for outputting information (e.g., visual or audio output) to a user such as, for example, a monitor, a display, a printer, an audio output jack, a speaker, etc. In some embodiments, the input device 906 and the output device 908 may comprise a single touchscreen device that can be used both to input information to the electronic system 900 and to output visual information to a user. The input device 906 and the output device 908 may communicate electrically with one or more of the memory device 902 and the electronic signal processor device 904.

In accordance with embodiments of the disclosure, an electronic system includes an input device, an output device, a processor device operably coupled to the input device and the output device, and a memory device operably coupled to the processor device and including a microelectronic device structure. The microelectronic device structure includes two blocks respectively comprising tiers vertically stacked relative to one another and individually including conductive material vertically neighboring insulative material. Each of the two blocks includes an array region and a contact region offset from the array region in a second horizontal direction orthogonal to the first horizontal direction. The array region includes vertically extending strings of memory cells therein. The contact region includes conductive contact structures therein that contact the conductive material at least some of the tiers of the stack structure. The array region has substantially uniform width in a first horizontal direction, while the contact region has different widths in the first horizontal direction. The microelectronic device structure also includes a dielectric slot structure horizontally interposed between the two blocks in the first horizontal direction.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

What is claimed is:

1. A microelectronic device, comprising:
a stack structure including levels of conductive material vertically alternating with levels of insulative material, the stack structure divided into blocks respectively comprising:
an array region having vertically extending strings of memory cells therein; and
a contact region horizontally offset from the array region in a first direction and having conductive contact structures in contact with at least some of levels of conductive material of the stack structure;
block isolation structures horizontally alternating with the blocks in a second direction orthogonal to the first direction and respectively vertically extending completely through the stack structure, at least one of the block isolation structures comprising:
a first portion horizontally overlapping the array region of each of two of the blocks in the first direction and horizontally extending in a substantially linear path in the first direction; and
a second portion horizontally overlapping the contact region of each of the two of the blocks in the first direction and horizontally extending in a non-linear path in the first direction and the second direction.

2. The microelectronic device of claim 1, wherein:
the blocks of the stack structure respectively further comprise a connecting region horizontally interposed between the array region and the contact region in the first direction; and
the at least one block isolation structures further comprises a third portion horizontally overlapping the connecting region of each of the two of the blocks in the first direction and horizontally extending in a substantially linear path in the first direction and the second direction.

3. The microelectronic device of claim 1, wherein at least one other of the block isolation structures is horizontally offset from the at least one of the block isolation structures in the second direction and comprises:
a first section horizontally overlapping the array region of each of two other of the blocks in the first direction and horizontally extending in a substantially linear path in the first direction; and
a second section horizontally overlapping the contact region of each of the two other of the blocks in the first direction and horizontally extending in an additional non-linear path in the first direction.

4. The microelectronic device of claim 1, wherein side surfaces of the block isolation structures are respectively non-planar in a vertical direction orthogonal to each of the first direction and the second direction.

5. The microelectronic device of claim 4, wherein the side surfaces of the block isolation structures are also respectively non-planar in the first direction.

6. The microelectronic device of claim 1, wherein the block isolation structures respectively have different horizontal widths, in the second direction, at different vertical elevations thereof.

7. The microelectronic device of claim 1, wherein the non-linear path of second portion of the at least one of the block isolation structures horizontally winds though some of the conductive contact structures within the contact region of each of the two of the blocks.

8. The microelectronic device of claim 1, wherein a minimum width, in the second direction, of respective ones of the block isolation structures is less than an additional minimum width, in the second direction, of respective ones of the conductive contact structures within the contact region of respective ones of the blocks.

9. A method of forming a microelectronic device, comprising:
forming pillar structures in an array region extending vertically through a stack structure;
forming patterns of inter-block openings in the stack structure extending vertically through the stack structure, the patterns of inter-block openings extending horizontally through the array region and a contact region offset from the array region in a first horizontal direction, at least one of the patterns of inter-block openings including:
a group of the inter-block openings within the array region and substantially linearly arranged relative to one another; and
an additional group of the inter-block openings within the contact region and at least partially non-linearly arranged relative to one another;
merging the inter-block openings of respective ones of the patterns of inter-block openings together to form block isolation slots; and
forming conductive contact structures in the contact region.

10. The method of claim 9, further comprising:
forming the stack structure to include levels of insulative material vertically alternating with levels of sacrificial material; and
replacing the sacrificial material in the levels of sacrificial material with a conductive material after merging the inter-block openings of the respective ones of the patterns of inter-block openings together to form the block isolation slots.

11. The method of claim 9, wherein merging the inter-block openings of respective ones of the patterns of inter-block openings together to form the block isolation slots comprises forming at least one of the block isolation slots to horizontally extend in a substantially linear path through the array region and to horizontally extend in a non-linear path through the contact region.

12. The method of claim 11, wherein merging the inter-block openings of respective ones of the patterns of inter-block openings together to form the block isolation slots further comprises forming an additional of the of block isolation slots to horizontally extend in an additional substantially linear path through each of the array region and the contact region.

13. The method of claim 9, further comprising substantially filling the block isolation slots with dielectric material to form block slot structures separating the stack structure into blocks in a second horizontal direction perpendicular to the first horizontal direction.

14. The method of claim 10, wherein merging the inter-block openings of respective ones of the patterns of inter-block openings together to form block isolation slots comprises:
removing portions of the levels of insulative material horizontally interposed between the inter-block openings using a first etch process; and
removing portions of the levels of sacrificial material horizontally interposed between the inter-block using a second etch process.

15. The method of claim 14, wherein forming conductive contact structures in the contact region comprises:
forming contact openings in the contact region vertically extending to various depths within the stack structure; and
substantially filling the contact openings with a fill material comprising additional conductive material.

16. The method of claim 15, further comprising implanting carbon into the portions of the levels of sacrificial material vertically underlying and within horizontal areas of contact openings.

17. The method of claim 9, wherein forming patterns of inter-block openings in the stack structure comprises forming each of the inter-block openings to have a maximum horizontally width within a range of from about 100 nanometers to about 200 nanometers.

18. The method of claim 9, further comprising forming the group of the inter-block openings within the array region to have substantially unform pitch between pairs of the inter-block openings horizontally neighboring one another.

19. The method of claim 18, further comprising further comprising forming the additional group of the inter-block openings within the contact region to have substantially unform pitch between additional pairs of the inter-block openings horizontally neighboring one another.

20. An electronic system, comprising:
an input device;
an output device;
a processor device operably coupled to the input device and the output device; and
a memory device operably coupled to the processor device and including a microelectronic device structure comprising:
two blocks respectively comprising tiers of a stack structure vertically stacked relative to one another and individually including conductive material vertically neighboring insulative material, the two blocks each including:
an array region having substantially uniform width in a first horizontal direction and including vertically extending strings of memory cells therein; and
a contact region offset from the array region in a second horizontal direction orthogonal to the first horizontal direction and having multiple, the contact region having different widths in the first horizontal direction, the contact region including conductive contact structures therein that contact the conductive material of at least some of the tiers of the stack structure; and
a dielectric slot structure horizontally interposed between the two blocks in the first horizontal direction.
